(19) United States
(12) Patent Application Publication
(10) Pub. No.: US 2026/0293189 A1
(43) Pub. Date: Sep. 24, 2026

(54) SEMICONDUCTOR STRUCTURE AND METHOD OF MANUFACTURING THE SAME

(71) Applicant: Taiwan Semiconductor Manufacturing Company, Ltd., Hsinchu (TW)

(72) Inventors: Chien-Hao Huang, Hsinchu City (TW); Yun-Feng Kao, New Taipei City (TW); Wen-Ling Lu, Taoyuan County (TW); Yu-Chien Chiu, Hsinchu County (TW); Katherine H. Chiang, New Taipei City (TW)

(21) Appl. No.: 19/088,088

(22) Filed: Mar. 24, 2025

(51) Int. Cl. H10D 30/63; H10D 30/01

(52) U.S. Cl. CPC H10D 30/63; H10D 30/025

(57) ABSTRACT

Various embodiments of the present disclosure are directed to a method for forming a semiconductor structure comprising vertical thin film transistors (TFTs) in which source and drain electrodes are self-aligned and in which a gate layer is fully cut between the vertical TFTs. Further, various embodiments of the present disclosure are directed to the semiconductor structure resulting from the method. According to an example of the method, a fin-shaped structure comprising a drain electrode and a pair of source electrodes is formed. An isolation wall is then formed covering a sidewall portion of the fin-shaped structure at a boundary region between the source electrodes. Further, a gate layer is deposited overlying and conformally lining the fin-shaped structure and the isolation wall and is cut at the boundary region.

### BACKGROUND

Integrated Circuits (ICs) may comprise millions or even billions of transistors, depending on their complexity and intended purpose. One type of transistor is a thin film transistor (TFT). A TFT is a specialized field-effect transistor (FET), which has its semiconductor channel formed through thin film deposition. Unlike a conventional FET, which has its semiconductor channel within a substrate on which it is formed, the semiconductor channel in a TFT is separate from the substrate on which it is formed. This provides greater flexibility when it comes to designing and fabricating TFTs.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIGS. 1A-1F illustrate various views of some embodiments of a semiconductor structure in which an isolation wall is between a pair of vertical thin-film transistors (TFTs).

FIGS. 2A-2F illustrate various views of some embodiments of a semiconductor structure comprising a plurality of vertical TFTs, a plurality of isolation walls, and a plurality of storage structures.

FIG. 3 illustrates a circuit diagram of some embodiments of the semiconductor structure of FIGS. 2A-2F.

FIG. 4 illustrates a perspective view of some alternative embodiments of the semiconductor structure of FIGS. 2A-2F in which portions of the semiconductor structure are cut away and in which the vertical TFTs have different profiles.

FIGS. 5A-5D illustrate various views of some alternative embodiments of the semiconductor structure of FIGS. 2A-2F further comprising a channel protection layer.

FIG. 6 illustrates a perspective view of some alternative embodiments of the semiconductor structure of FIGS. 5A-5D in which portions of the semiconductor structure are cut away and in which the vertical TFTs have different profiles.

FIGS. 7A-7D illustrate various views of some alternative embodiments of the semiconductor structure of FIGS. 2A-2F further comprising a channel protection layer and a source/drain liner.

FIGS. 8A and 8B illustrate perspective views of various different embodiments of the semiconductor structure of FIGS. 7A-7D in which portions of the semiconductor structure are cut away.

FIGS. 9A-9D to FIGS. 27A-27D illustrate a series of views of some embodiments of a method for forming a semiconductor structure comprising a plurality of vertical TFTs and a plurality of isolation walls between the vertical TFTs.

FIG. 28 illustrates a block diagram of some embodiments of the method of FIGS. 9A-9D to FIGS. 27A-27D.

FIGS. 29A-29F to FIGS. 30A-30D illustrate a series of views of some alternative embodiments of the method of FIGS. 9A-9D to FIGS. 27A-27D in which no interlayer dielectric (ILD) layer is formed between etches to cut a gate layer.

FIGS. 31A-31F to FIGS. 32A-32D illustrate a series of views of some alternative embodiments of the method of FIGS. 9A-9D to FIGS. 27A-27D in which a channel protection layer is formed.

FIGS. 33A-33F to FIGS. 35A-35D illustrate some alternative embodiments of the method of FIGS. 9A-9D to FIGS. 27A-27D in which a channel protection layer and a source/drain liner are formed.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

Types of thin film transistor (TFTs) include planar TFTs and vertical TFTs. In some embodiments of a planar TFT, a gate electrode underlies a semiconductor channel, which extends laterally from a source electrode to a drain electrode. As result, the gate length is defined by lateral spacing between the source and drain electrodes. However, this lateral spacing is susceptible to large fluctuations due to process variation from film deposition, lithography, and etching while forming the source and drain electrodes. Further, these fluctuations may result in large fluctuations in electrical properties of the planar TFT and may increase the difficulty scaling down the planar TFT.

In some embodiments of a vertical TFT, a drain electrode overlies a source electrode, and a semiconductor channel extends vertically from the drain electrode to the source electrode. Further, the semiconductor channel and the drain electrode underlie and are recessed into a gate electrode. As a result, the gate length is defined by vertical spacing between the source and drain electrodes, which may be controlled solely by film deposition. Because the vertical spacing may be controlled solely by film deposition, the vertical spacing is less susceptible to process variation, which aids in scaling down the vertical TFT.

The vertical TFT may be formed by a method in which the source and drain electrodes are separately formed with separate, non-self-aligned patterns. However, this may lead to misalignment and reduced overlap between the semiconductor channel and the source electrode, which may degrade electrical properties of the vertical TFT. For example, ON current (Iₒₙ) may be reduced and/or parasitic resistance (Rₚ) may be increased. Further, when the vertical TFT is formed in a memory array using this method, the gate electrode may correspond to a word line and extend continuously, along with its gate dielectric layer, along a row. However, this may increase parasitic capacitance and degrade memory speed.

The vertical TFT may alternatively be formed by a method in which the source and drain electrodes are formed together with a common pattern and are hence self-aligned. This method may alleviate the issues regarding misalignment. However, when the vertical TFT is formed in a memory array by this method, challenges may arise.

The forming of the source and drain electrodes may yield fin-shaped structures elongated along columns of the memory array and in which the source electrodes and drain electrodes are. A multi-layer film, including a semiconductor channel layer and a gate electrode layer, may be deposited overlying and conforming to the fin-shaped structures. Further, the multi-layer film may be cut by etching at boundary regions between rows and columns to ideally segment the multi-layer film into segments individual to vertical TFTs. However, in practice, the etching may only remove gate material directly over the fin-shaped structures and may leave gate material on sidewalls of the fin-shaped structures. Additional etching would damage the drain electrodes. Hence, the gate layer may not be fully cut and there may be leakage paths along sidewalls of the fin-shaped structures, between gate electrodes.

Various embodiments of the present disclosure are directed to a method for forming a semiconductor structure comprising vertical TFTs in which source and drain electrodes are self-aligned and in which a gate layer is fully cut between the vertical TFTs. Further, various embodiments of the present disclosure are directed to the semiconductor structure.

According to some embodiments of the method, conductive lines are formed elongated in a row-wise direction, a conductive layer is deposited overlying and spaced from the conductive lines, and a common etch is performed into the conductive layer and conductive lines. The common etch forms source electrodes from the conductive lines and in a plurality of rows and a plurality of columns. Further, the common etch forms drain electrodes from the conductive layer and respectively overlying the source electrodes.

Because of the common etch, the source and drain electrodes are self-aligned with each other. This may prevent electrical performance degradation of the vertical TFTs from misalignment. Further, the source electrodes may have a distinctive shape with a trapezoidal profile increasing in width from top to bottom or a rectangular profile.

Forming the source and drain electrodes as above yields fin-shaped structures extending along the columns and in which the source and drain electrodes are arranged. Continuing with some embodiments of the method, a so-called isolation-first process is performed to form isolation walls separating the rows. A multi-layer film, including a semiconductor channel layer and a gate electrode layer, is then deposited overlying and conforming to the fin-shaped structures and the isolation walls. Further, the multi-layer film is cut by etching at boundary regions between the rows and boundary regions between the columns to segment the multi-layer film into segments individual to the vertical TFTs.

Because of the isolation walls, sidewalls of the fin-shaped structures are covered at boundary regions between the rows. Hence, portions of the multi-layer film that would otherwise deposit on the sidewalls at the boundary regions instead deposit on top surfaces of the isolation walls. Hence, these portions of the multi-layer film are horizontally extending instead of vertically extending. This significantly reduces the amount of vertical etching needed to fully cut the multi-layer film, which enlarges the process window. Further, leakage paths along the sidewalls are prevented and parasitic capacitance is reduced.

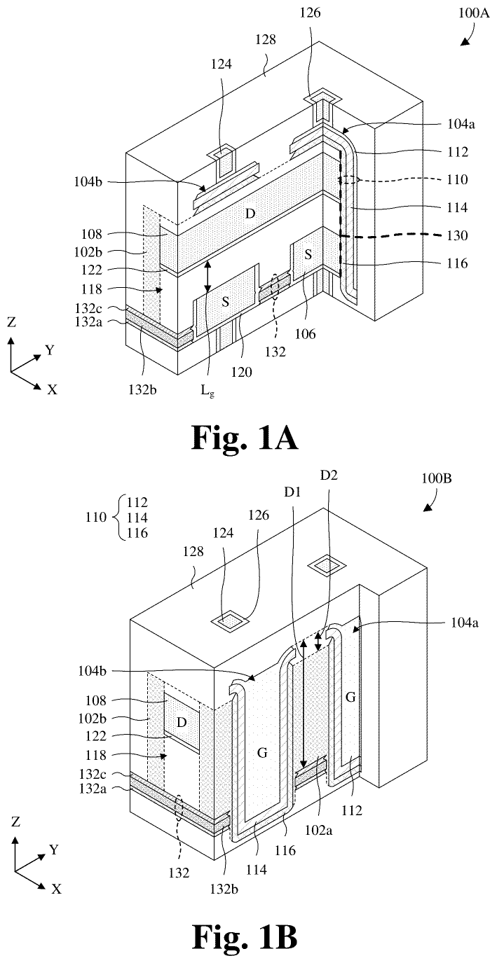

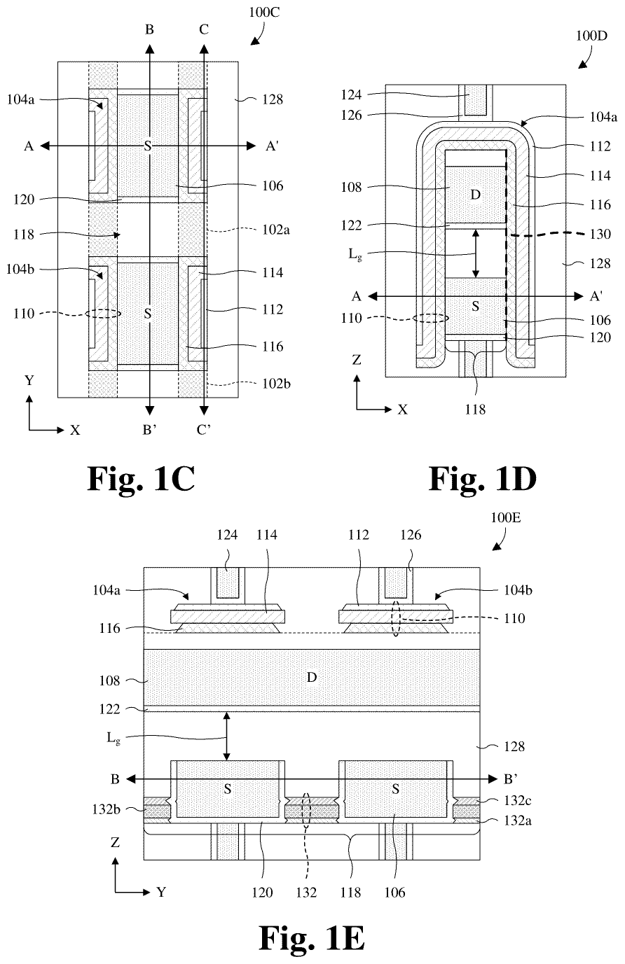

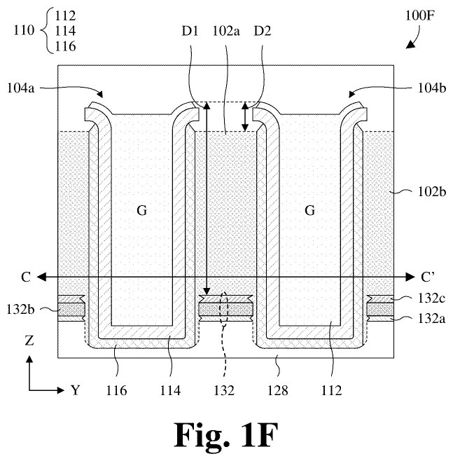

With reference to FIGS. 1A-1F, various views 100A-100F of some embodiments of a semiconductor structure are provided in which an isolation wall 102a is between a first vertical TFT 104a and a second vertical TFT 104b. FIGS. 1A and 1B correspond to perspective views 100A, 100B in which portions have been cut away. In FIG. 1A, the cut-away portion corresponds to the bottom-right quadrant demarcated by line A-A′ and line B-B′ in FIG. 1C. In FIG. 1B, the cut-away portion corresponds to the bottom-right quadrant demarcated by line A-A′ and line C-C′ in FIG. 1C. FIGS. 1D-1F correspond to cross-sectional views 100D-100F respectively along lines A-A′, B-B′, and C-C′ in FIG. 1C, and FIG. 1C corresponds to a top-sectional view 100C along lines A-A′, B-B′, and C-C′ respectively in FIGS. 1D-1F.

The first and second vertical TFTs 104a, 104b comprise individual source electrodes 106 (also labeled S) and a common drain electrode 108 (also labeled D) overlying and spaced from the source electrodes 106. Further, the first and second vertical TFTs 104a, 104b comprise individual film stacks 110 overlying the common drain electrode 108 and extending vertically from the common drain electrode 108 respectively to the source electrodes 106. The film stacks 110 comprise individual gate electrodes 112 (also labeled G), individual gate dielectric layers 114, and individual semiconductor channels 116. The gate dielectric layers 114 separate the gate electrodes 112 from semiconductor channels 116, which separate the gate dielectric layers 114 from the common drain electrode 108 and the source electrodes 106.

During manufacture of the semiconductor structure, the common drain electrode 108 and the source electrodes 106 are formed self-aligned with each other. A pair of conductive lines are formed elongated laterally in an X direction, a conductive layer is deposited over the pair of conductive lines, and an etch is performed into the conductive layer and the pair of conductive lines. The etch forms the common drain electrode 108 from the conductive layer and forms the source electrodes 106 respectively from the pair of conductive lines.

Because the common drain electrode 108 and the source electrodes 106 are self-aligned, misalignment between constituents of the first and second vertical TFTs 104a, 104b may be reduced. As a result, electrical properties of the first and second vertical TFTs 104a, 104b may have higher uniformity and less degradation during bulk manufacture of the first and second vertical TFTs 104a, 104b, which may increase manufacturing yields. Further, because of the self-aligned process, the source electrodes 106 may have a unique shape.

In some embodiments, the source electrodes 106 may have a rectangular prism shape or a trapezoidal prism shape. In some embodiments, each of the source electrodes 106 has a rectangular cross section, or a trapezoidal cross section increasing in width from top to bottom, in a cross-sectional plane extending in the X direction and a Z direction. In some embodiments, each of the source electrodes 106 has a width in the X direction, where a value of the width at a top of that source electrode is less than or equal to a value of the width at a bottom of that source electrode. In some embodiments, the source electrodes 106 may have top surfaces and sidewalls that meet in cross-sectional planes extending in the X and Z directions and at angles of 80-85 degrees, 85-90 degrees, 90 degrees, or some other suitable number of degrees.

Also, during manufacture of the semiconductor structure, the common drain electrode 108 and the source electrodes 106 are formed integrated into a fin-shaped structure 118 that is elongated laterally in a Y direction. The isolation wall 102a is formed elongated laterally in the X direction and covers sidewalls of the fin-shaped structure 118 at a boundary region between the source electrodes 106. Further, a multi-layer film is deposited on the fin-shaped structure 118 and the isolation wall 102a and is cut into the film stacks 110 by etching.

Because the isolation wall 102a covers the sidewalls of the fin-shaped structure 118 at the boundary region between the source electrodes 106, portions of the multi-layer film that would otherwise deposit on the sidewalls at the boundary region instead deposit on a top surface of the isolation wall 102a. Hence, these portions of the multi-layer film are horizontally extending instead of vertically extending while crossing the boundary region in the Y direction. This significantly reduces the amount of vertical etching needed to fully cut the multi-layer film, which alleviates challenges associated with cutting the multi-layer film.

For example, focusing on FIG. 1B or 1F, fully etching a vertically extending portion of the multi-layer film would depend on vertical etching to a depth D1. However, this would be time consuming and likely cut into and damage the common drain electrode 108. Further, only vertically etching to a depth D2 (e.g., equal to a thickness of the multi-layer film or some other suitable value), would fail to fully cut the vertically extending boundary portion and would lead to leakage current between the gate electrodes 112. In contrast, a horizontally extending portion of the multi-layer film may be fully cut by vertical etching to the depth D2, which would not damage the common drain electrode 108.

In view of the foregoing, the isolation wall 102a allows the multi-layer film to be cut at the boundary region between the source electrodes 106 without having to choose between damaging the common drain electrode 108 and leakage current between the gate electrodes 112. This, in turn, improves manufacturing yields and reduces manufacturing costs. Further, fully cutting the multi-layer film has the added benefit of reducing parasitic capacitance, which may enhance the switching speed of the first and second vertical TFTs 104a, 104b. For example, fully cutting the multi-layer film may reduce the areas of parasitic capacitance formed in part by dielectric and/or conductive material of the multi-layer film.

Because of the isolation wall 102a, as well as because of a pair of additional isolation walls 102b between which the first and second vertical TFTs 104a, 104b are arranged in the Y direction, constituents of the film stacks 110 may have a unique layout. For example, focusing on FIG. 1C, the gate electrodes 112 may be laterally recessed into the gate dielectric layers 114, such that the gate dielectric layers 114 wrap around sides of the gate electrodes 112. Similarly, the gate dielectric layers 114 may be laterally recessed into the semiconductor channels 116, such that the semiconductor channels 116 wrap around sides of the gate dielectric layers 114. Further, the gate electrodes 112 may have individual dimensions in the Y direction that are less than individual dimensions of the source electrodes 106 in the Y direction.

In some embodiments, the gate dielectric layers 114 and the semiconductor channels 116 have C-shaped or reverse C-shaped layouts at an elevation level with the source electrodes 106. Further, in some embodiments, the gate dielectric layers 114 and the semiconductor channels 116 have C-shaped or reverse C-shaped layouts at an elevation level with the common drain electrode 108. Other suitable layouts are, however, amenable.

With continued reference to FIGS. 1A-1F, the source electrodes 106 comprise individual source bodies and individual source liners 120. Note that for ease of illustration, the source bodies are labeled as the source electrodes 106. The source liners 120 extend along bottom surfaces of the source bodies and along sidewalls of the source bodies. The source liners 120 may, for example, be configured to prevent outward diffusion of material from the source bodies and/or to increase adhesion of the source bodies to surrounding structure. In alternative embodiments, the source liners 120 may be omitted.

The common drain electrode 108 comprises a drain body and a drain liner 122. Note that for ease of illustration, the drain body is labeled as the common drain electrode 108. The drain liner 122 extends along a bottom surface of the drain body and along sidewalls of the drain body. The drain liner 122 may, for example, be configured to prevent outward diffusion of material from the drain body and/or to increase adhesion of the drain body to surrounding structure. In alternative embodiments, the drain liner 122 may be omitted.

The source bodies of source electrodes 106 and the drain body of the common drain electrode 108 are conductive and may, for example, be or comprise copper, aluminum, tungsten, aluminum copper, titanium, tantalum, some other suitable conductive material, or any combination of the foregoing. The source liners 120 and the drain liner 122 are conductive and may, for example, be or comprise titanium nitride, tantalum nitride, some other suitable conductive material, or any combination of the foregoing.

A plurality of vias 124 extend from the first and second vertical TFTs 104a, 104b and may, for example, correspond to a back-end-of-line (BEOL) interconnect structure in which the first and second vertical TFTs 104a, 104b are. Some of the plurality of vias 124 are individual to the source electrodes 106 and underlie and extend respectively from the source electrodes 106. Some of the plurality of vias 124 are individual to the gate electrodes 112 and overlie and extend respectively from the gate electrodes 112. The plurality of vias 124 comprise individual via bodies and individual via liners. Note that for ease of illustration, the via bodies are labeled as the plurality of vias 124.

The via liners 126 extend along bottom surfaces of the via bodies and sidewalls of the via bodies. The via liners 126 may, for example, be configured to prevent outward diffusion of material from the via bodies and/or to increase adhesion of the via bodies to surrounding structure. In alternative embodiments, the via liners 126 may be omitted. The via bodies are conductive and may, for example, be or comprise copper, aluminum copper, aluminum, tungsten, some other suitable conductive material, or any combination of the foregoing. The via liners 126 are conductive and may, for example, be or comprise titanium nitride, tantalum nitride, some other suitable conductive material, or any combination of the foregoing.

The gate electrodes 112 may, for example, be or comprise aluminum, tantalum, titanium, some other suitable conductive material, or any combination of the foregoing. The gate dielectric layers 114 may, for example, be or comprise silicon oxide, a high k dielectric material, some other suitable dielectric material, or any combination of the foregoing. The high k dielectric material may, for example, be or comprise hafnium oxide, aluminum oxide, aluminum nitride, some other suitable high k dielectric material, or any combination of the foregoing. The semiconductor channels 116 may, for example, be or comprise indium gallium zinc oxide (e.g., IGZO), tin oxide (e.g., SnO), indium oxide (e.g., InO), some other suitable semiconductor material, or any combination of the foregoing. In some embodiments, the semiconductor channels 116 form Schottky junctions with the plurality of source electrodes 106 and the plurality of drain electrodes 108.

A dielectric structure 128 surrounds the first and second vertical TFTs 104a, 104b and fills gaps between the source electrodes 106, the common drain electrode 108, and the film stacks 110. For example, a portion of the dielectric structure 128 may separate the source electrodes 106 from the common drain electrode 108 in the Z direction to define the gate lengths L_{g} for the first and second vertical TFTs 104a, 104b. The dielectric structure 128 may, for example, comprise a plurality of interlayer dielectric (ILD) layers that are stacked. Further, the dielectric structure 128 may, for example, be or comprise silicon oxide, silicon oxynitride, undoped silicate glass (USG), phosphosilicate glass (PSG), borophosphosilicate glass (BPSG), some other suitable dielectric material, or any combination of the foregoing.

In some embodiments, and focusing on FIG. 1A or 1D, a portion of the dielectric structure 128 forms a common sidewall 130 with the source electrodes 106 and the common drain electrode 108. The common sidewall 130 comprises individual sidewalls of the dielectric structure 128, the source electrodes 106, and the common drain electrode 108. The common sidewall 130 may, for example, have a smooth or planar profile facing in the X direction and/or may, for example, correspond to a sidewall of the fin-shaped structure 118. Further, the common sidewall 130 may, for example, be a product of the self-aligned process by which the source electrodes 106 and the common drain electrode 108 are formed.

An etch stop layer 132 further surrounds the first and second vertical TFTs 104a, 104b and separates the source electrodes 106 from each other, at bottoms of the source electrodes 106. The etch stop layer 132 comprises a first layer 132a, a second layer 132b over the first layer 132a, and a third layer 132c over the second layer 132b. In alternative embodiments, the etch stop layer 132 may comprise more or less layers and/or may comprise only a single layer. For example, any two of the layers (e.g., the second and third layers 132b, 132c) may be omitted, such that the etch stop layer 132 and the remaining layer (e.g., the first layer 132a) are the same. In some embodiments, the first layer 132a is or comprises aluminum nitride, the second layer 132b is or comprises silicon oxycarbide, and the third layer 132c is or comprises aluminum oxide. Alternatively, any one or more of the layers may be some other suitable material.

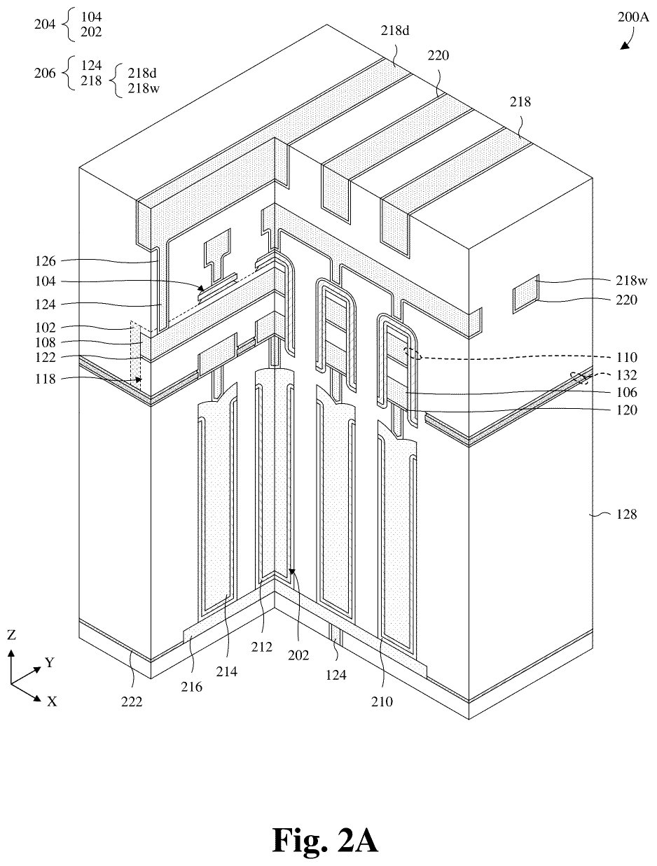

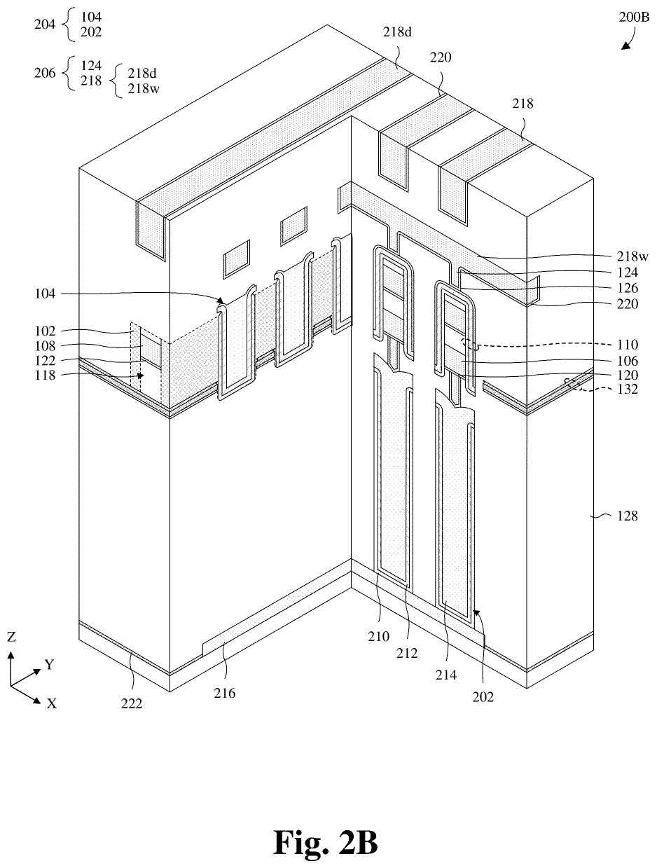

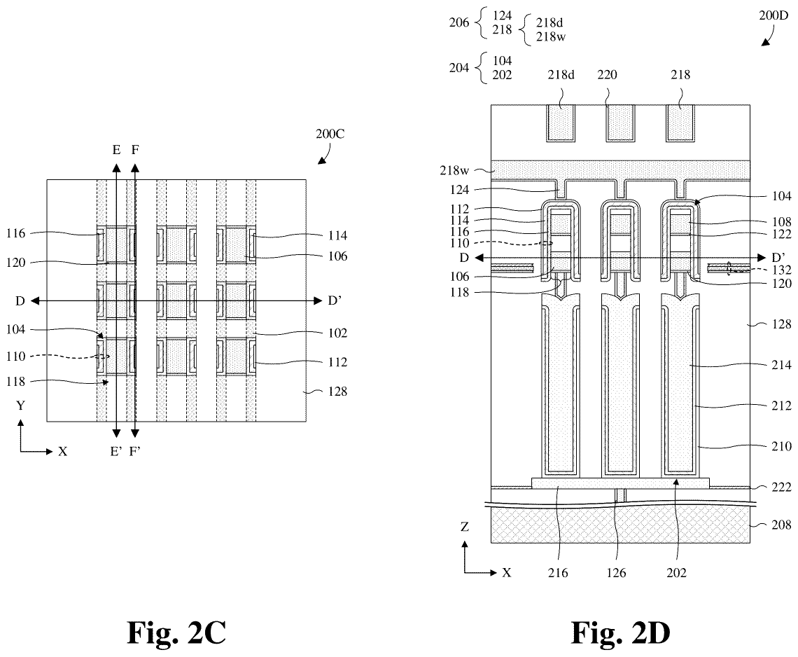

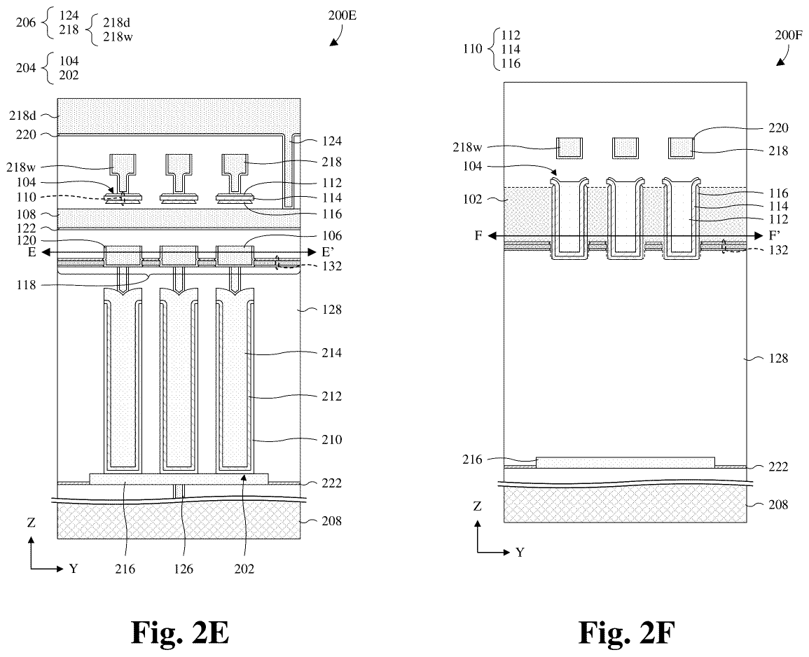

With reference to FIGS. 2A-2F, various views 200A-200F of some embodiments of a semiconductor structure comprising a plurality of vertical TFTs 104, a plurality of isolation walls 102, and a plurality of storage structures 202 are provided. FIGS. 2A and 2B correspond to perspective views 200A, 200B in which portions have been cut away. In FIG. 2A, the cut-away portion corresponds to the bottom-right quadrant demarcated by line D-D′ and line E-E′ in FIG. 2C. In FIG. 2B, the cut-away portion corresponds to the bottom-right quadrant demarcated by line D-D′ and line F-F′ in FIG. 2C. FIGS. 2D-2F correspond to cross-sectional views 200D-200F respectively along lines D-D′, E-E′, and F-F′ in FIG. 2C, and FIG. 2C corresponds to a top-sectional view 200C along lines D-D′, E-E′, and F-F′ respectively in FIGS. 2D-2F.

The plurality of vertical TFTs 104 are each as their counterparts are in FIGS. 1A-1F. Further, the plurality of vertical TFTs 104 respectively overlie and are electrically coupled with the plurality of storage structures 202 to form a plurality of one-transistor one-storage node (1T-1SN) memory structures 204. The plurality of 1T-1SN memory structures 204 each comprise a vertical TFT and a storage structure and may, for example, correspond to dynamic random-access memory (DRAM), magnetoresistive random-access memory (MRAM), resistive random-access memory (RRAM), phase-change random-access memory (PCRAM), or the like. In alternative embodiments, the plurality of storage structures 202 may be omitted and the plurality of vertical TFTs 104 may instead be employed as electronic fuses (eFuses).

The plurality of 1T-1SN memory structures 204 are in a BEOL interconnect structure 206, which overlies a substrate 208. Note that for ease of illustration, the substrate 208 is not shown in the perspective views 200A, 200B of FIGS. 2A and 2B. The substrate 208 may, for example, be or comprise a silicon substrate, a silicon-on-insulator (SOI) substrate, some other suitable type of semiconductor substrate, or some other suitable type of substrate. Further, the plurality of 1T-1SN memory structures 204 are in a plurality of rows and a plurality of columns to form a memory array. The plurality of rows extend laterally in an X direction and total three, whereas the plurality of columns extend laterally in a Y direction and total three. In alternative embodiments, there may be more or less rows and/or more or less columns.

The plurality of vertical TFTs 104 comprise a plurality of source electrodes 106, a plurality of drain electrodes 108, and a plurality of film stacks 110. The plurality of source electrodes 106 are individual to the plurality of vertical TFTs 104 and comprise individual source bodies and individual source liners 120. The plurality of drain electrodes 108 are individual to the plurality of columns, and each is elongated laterally along an individual column and overlies and is spaced from source electrodes in the individual column. As a result, the plurality of drain electrodes 108 may be regarded as bit lines for the memory array. Further, the plurality of drain electrodes 108 comprise individual drain bodies and individual drain liners 122. As was above, the source and drain bodies are labeled as the plurality of source electrodes 106 and the plurality of drain electrodes 108 for ease of illustration.

The plurality of film stacks 110 respectively overlie the plurality of drain electrode 108 and extend vertically from drain electrode to source electrode. The film stacks 110 comprise individual gate electrodes 112, individual gate dielectric layers 114, and individual semiconductor channels 116. Note that for ease of illustration, constituents of the film stacks 110 are not labeled in FIGS. 2A and 2B. The gate dielectric layers 114 separate the gate electrodes 112 from the semiconductor channels 116, which separate the gate dielectric layers 114 from the plurality of drain electrode 108 and the plurality of source electrodes 106.

Focusing on FIG. 2C, the plurality of isolation walls 102 alternate with the plurality of rows in the Y direction to partially separate the plurality of rows. As above, the plurality of isolation walls 102 prevent a multi-layer film from depositing on sidewalls of fin-shaped structures 118 in which the plurality of source electrodes 106 and the plurality of drain electrodes 108 are arranged. As a result, the multi-layer film is horizontally extending, rather than vertically extending, while crossing boundary regions between the plurality of rows. Further, when cutting the multi-layer film into the plurality of film stacks 110, the amount of vertical etching to fully cut the multi-layer film at the boundary regions is significantly reduced. This allows the multi-layer film to be fully cut without damaging the plurality of drain electrodes 108.

The plurality of storage structures 202 correspond to metal-insulator-metal (MIM) capacitors, whereby the plurality of 1T-1SN memory structures 204 may, for example, correspond to DRAM. Alternatively, the plurality of storage structures 202 may have a different structure for different types of memory, such as MRAM, PCRAM, RRAM, etc. The plurality of storage structures 202 comprise individual bottom electrodes 210, individual insulators 212, and individual top electrodes 214. The bottom electrodes 210 overlie and electrically couple to a bottom-electrode pad 216 common to the bottom electrodes 210. The insulators 212 respectively overly and are recessed into the bottom electrodes 210, and the top electrodes 214 respectively overly and are recessed into the insulators 212. Further, the top electrodes 214 are electrically coupled respectively to the plurality of source electrodes 106.

In some embodiments, the bottom electrodes 210 and/or the top electrodes 214 are or comprise titanium, tantalum, titanium nitride, tantalum nitride, some other suitable conductive material, or any combination of the foregoing. In some embodiments, the insulators 212 are or comprise silicon oxide, a high k dielectric material, some other suitable dielectric material, or any combination of the foregoing. The high k dielectric material may, for example, be or comprise hafnium oxide, aluminum oxide, aluminum nitride, some other suitable high k dielectric material, or any combination of the foregoing. In some embodiments, the bottom-electrode pad 216 is or comprises copper, aluminum, aluminum copper, titanium, tantalum, some other suitable conductive material, or any combination of the foregoing.

The BEOL interconnect structure 206 comprises a plurality of wires 218 and a plurality of vias 124, which are grouped into a plurality of wire levels and a plurality of via levels that are alternatingly stacked over and away from the substrate 208 to define conductive paths. The plurality of vias 124 comprise individual via bodies and individual via liners 126, whereas the plurality of wires 218 comprise individual wire bodies and individual wire liners 220. Note that for ease of illustration, the via bodies and the wire bodies are labeled respectively as the plurality of vias 124 and the plurality of wires 218.

The via liners 126 extend along bottom surfaces of the via bodies and sidewalls of the via bodies. Further, the via liners 126 may, for example, be configured to prevent outward diffusion of material from the via bodies and/or to increase adhesion of the via bodies to surrounding structure. In alternative embodiments, the via liners 126 may be omitted. The wire liners 220 extend along bottom surfaces of the wire bodies and sidewalls of the wire bodies. Further, the wire liners 220 may, for example, be configured to prevent outward diffusion of material from the wire bodies and/or to increase adhesion of the wire bodies to surrounding structure. In alternative embodiments, the wire liners 220 may be omitted.

The via bodies and the wire bodies are conductive and may, for example, be or comprise copper, aluminum copper, aluminum, tungsten, some other suitable conductive material, or any combination of the foregoing. The via liners 126 and the wire liners 220 are conductive and may, for example, be or comprise titanium nitride, tantalum nitride, some other suitable conductive material, or any combination of the foregoing.

For some of the plurality of wires 218 and some of the plurality of vias 124, wire bodies of these wires and via bodies of these vias correspond to different portions of conductive body layers that each span a wire level and a via level. Similarly, wire liners of these wires and via liners of these vias correspond to different portions of conductive liner layers that each span a wire level and a via level. As an example, focusing on FIG. 1A, wires in the wire level immediately above the plurality of vertical TFTs 104 and vias in the via level extending from the wire level to the plurality of vertical TFTs 104 have individual bodies and individual liners corresponding to different portions of conductive body and liner layers.

The plurality of wires 218 comprise a plurality of word lines 218w and a plurality of drain wires 218d. The plurality of word lines 218w respectively overlie and are spaced from the plurality of vertical TFTs 104. Further, the plurality of word lines 218w are individual to the plurality of rows and each is electrically coupled to gate electrodes in an individual row by vias of the plurality of vias 124. The plurality of drain wires 218d overlie and are spaced from the plurality of word lines 218w. Further, the plurality of drain wires 218d are individual to the plurality of columns and each is electrically coupled to a drain electrode in an individual column by vias of the plurality of vias 124. Such vias span multiple via levels (e.g., two via levels) and are hence longer than other vias of the plurality of vias 124.

The plurality of vias 124 comprise a via extending from a bottom surface of the bottom-electrode pad 216 to electrically couple the bottom-electrode pad 216 to underlying portions of the BEOL interconnect structure 206. Further, in some embodiments, the bottom-electrode pad 216 may be regarded as a wire of the plurality of wires 218.

A dielectric structure 128, as well a first etch stop layer 132 and a second etch stop layer 222, surround the plurality of 1T-1SN memory structures 204. The first etch stop layer 132 is at bottoms of the plurality of source electrodes 106, whereas the second etch stop layer 222 is at a bottom of the bottom-electrode pad 216. Note that for ease of illustration, constituents of the first etch stop layer 132 are not labeled. The dielectric structure 128 and the first etch stop layer 132 may, for example, be as their counterparts are described with regard to FIGS. 1A-1F. Further, the second etch stop layer 222 may, for example, be or comprise aluminum nitride, silicon nitride, silicon oxynitride, silicon oxycarbide, aluminum oxide, silicon carbide, some other suitable dielectric material, or any combination of the foregoing.

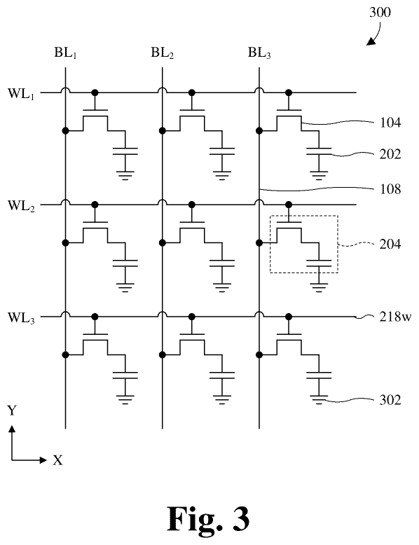

With reference to FIG. 3, a circuit diagram 300 of some embodiments of the semiconductor structure of FIGS. 2A-2F is provided. The plurality of 1T-1SN memory structures 204 are in a plurality of rows and a plurality of columns to form a memory array. The plurality of rows extend laterally in the X direction and total three, and the plurality of columns extend laterally in the Y direction and total three. Alternatively, there may be more or less rows and/or more or less columns.

The plurality of 1T-1SN memory structures 204 comprise individual vertical TFTs 104 and individual storage structures 202. The individual storage structures 202 correspond to capacitors, such that the plurality of 1T-1SN memory structures 204 may, for example, correspond to DRAM. Alternatively, the plurality of storage structures 202 may have a different structure for different types of memory. The storage structures 202 are electrically coupled respectively from sources of the vertical TFTs 104 (see, e.g., the plurality of source electrodes 106 in FIGS. 2A-2F) to a ground terminal 302 by the BEOL interconnect structure 206 of FIGS. 2A-2F. Note that for ease of illustration, the ground terminal 302 is individually illustrated for each of the plurality of 1T-1SN memory structures 204.

The plurality of word lines 218w correspond to the plurality of rows and are labeled WL₁ to WL₃, where the label subscript corresponds to row number. Further, the plurality of word lines 218w extend laterally in parallel in the X direction and are each electrically coupled to gates of vertical TFTs (see, e.g., the plurality of gate electrodes 112 in FIGS. 2A-2F) in the corresponding row by the BEOL interconnect structure 206 of FIGS. 2A-2F. The plurality of drain electrodes 108 correspond to the plurality of columns and serve as bit lines. Hence, the plurality of drain electrodes 108 are labeled BL₁ to BL₃, where BL stands for bit line and the label subscript corresponds to column number. Further, the plurality of drain electrodes 108 extend laterally in parallel in the Y direction and each forms drains of vertical TFTs in the corresponding column.

During use of the memory array, the plurality of word lines 218w and the plurality of vertical TFTs 104 are used to select a particular row of the memory array and then the plurality of drain electrodes 108 are used to read from or write to the selected row. For example, word line WL₁ may be biased so semiconductor channels (see, e.g., the plurality of semiconductor channels 116 in FIGS. 2A-2F) for vertical TFTs in row 1 conduct while the remaining word lines are biased so semiconductor channels for vertical TFTs in the remaining rows are non-conductive. Thereafter, the plurality of drain electrodes 108 may be appropriately biased to read from or write to the storage structures in row 1.

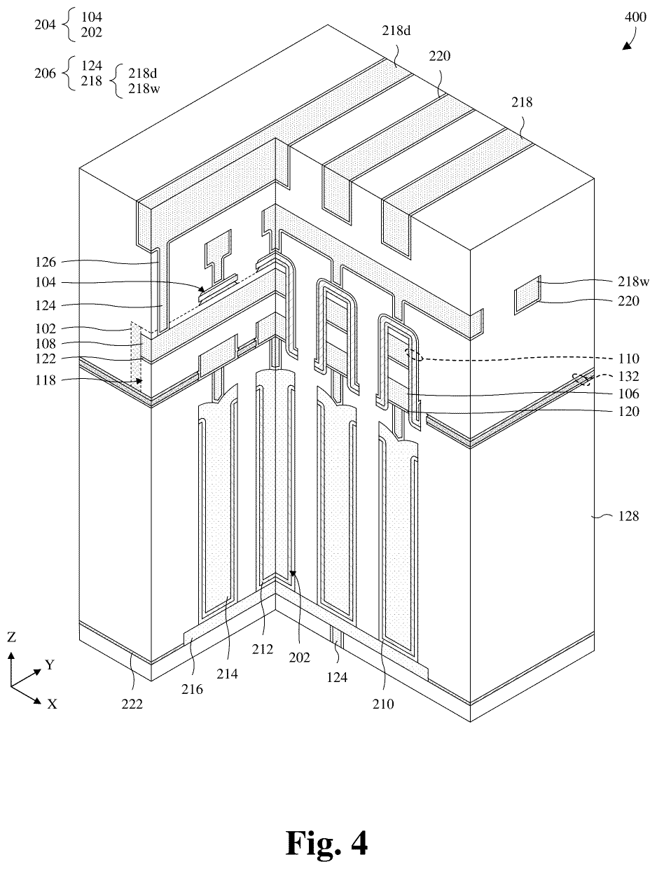

With reference to FIG. 4, a perspective view 400 of some alternative embodiments of the semiconductor structure of FIGS. 2A-2F is provided in which portions of the semiconductor structure are cut away and in which the plurality of film stacks 110 have different cross-sectional profiles. The semiconductor structure is the same as that illustrated and described with regard to FIGS. 2A-2F, except for the different profiles, and the cut-away portion corresponds to the bottom-right quadrant demarcated by line D-D′ and line E-E′ in FIG. 2C.

At bottoms of the plurality of film stacks 110, the plurality of film stacks 110 flare outward along the X direction. Further, film stacks at outermost columns of the semiconductor structure (e.g., the first and last columns), have an asymmetric profile in a cross-sectional plane extending in the X direction and the Z direction. In contrast, film stacks at interior columns of the semiconductor structure have an asymmetric profile. The difference in cross-sectional profiles between FIG. 3 and FIGS. 2A-2F may, for example, be due to differences in widths of masks used to form the plurality of film stacks 110.

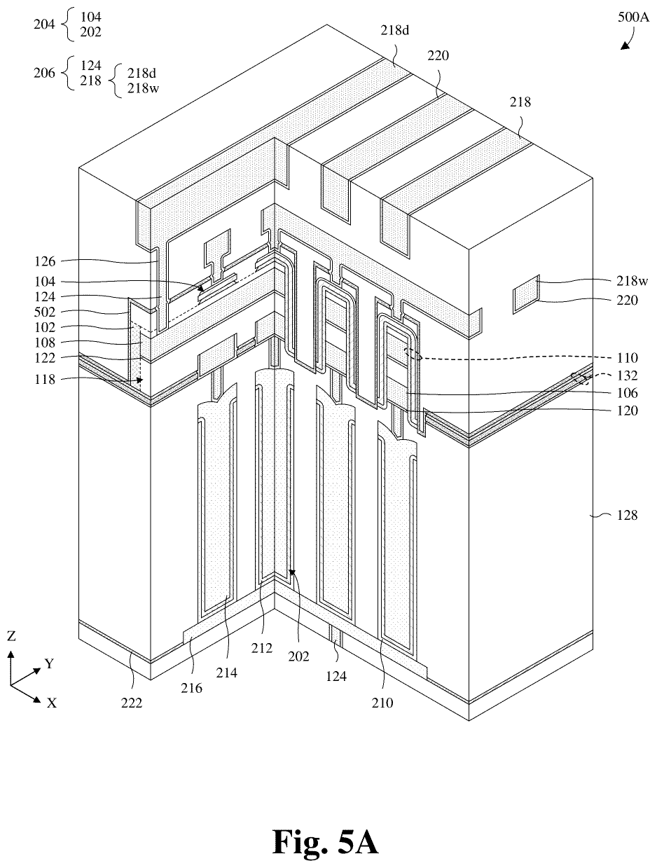

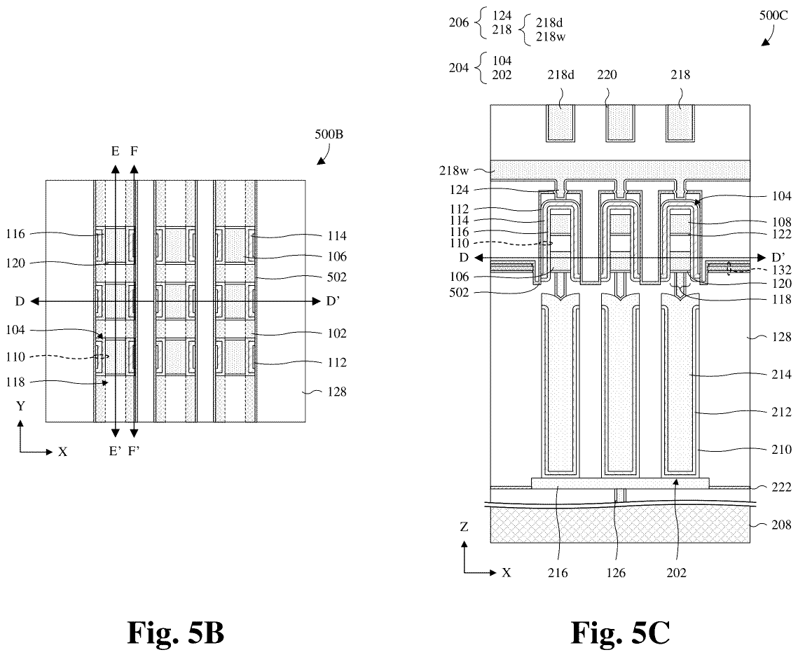

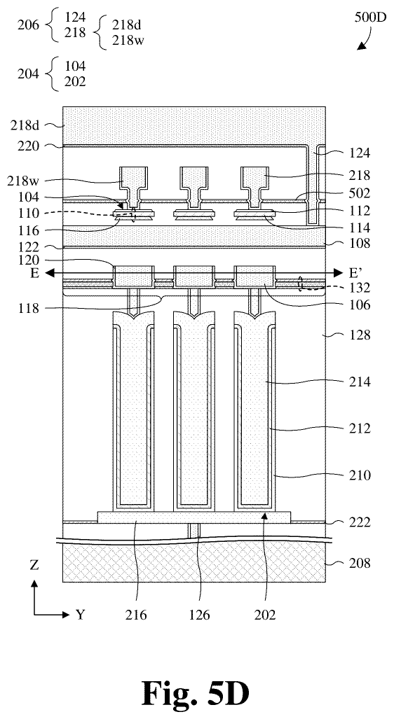

With reference to FIGS. 5A-5D, various views 500A-500D of some alternative embodiments of the semiconductor structure of FIGS. 2A-2F are provided in which the semiconductor structure further comprises a channel protection layer 502. FIG. 5A corresponds to a perspective view 500A in which portions have been cut away, said portions corresponding to the bottom-right quadrant demarcated by line D-D′ and line E-E′ in FIG. 5B. FIGS. 5C and 5D correspond to cross-sectional views 500C, 500D respectively along lines D-D′ and E-E′ in FIG. 5B, and FIG. 5B corresponds to a top-sectional view 500B along lines D-D′ and E-E′ respectively in FIGS. 5C and 5D.

The channel protection layer 502 overlies the plurality of vertical TFTs 104, the plurality of fin-shaped structures 118, and the plurality of isolation walls 102. Further, the channel protection layer 502 extends along sidewalls of the plurality of vertical TFTs 104 and sidewalls of the plurality of isolation walls 102 to an elevation recessed below the plurality of vertical TFTs 104. As a result, the channel protection layer 502 surrounds the plurality of vertical TFTs 104 and the plurality of isolation walls 102. The channel protection layer 502 is configured to block hydrogen, oxygen, and other errant particles from diffusing to the plurality of vertical TFTs 104. Such errant particles may, for example, enter the semiconductor structure during manufacture of the semiconductor structure, at processing steps performed after formation of the plurality of vertical TFTs 104. The channel protection layer 502 may, for example, be or comprise aluminum oxide (e.g., AlO), silicon oxycarbide (SiOC), chromium oxide (e.g., Cr₂O₃), hafnium oxide (e.g., HfO), other suitable material, or any combination of the foregoing.

By blocking errant particles from reaching the plurality of vertical TFTs 104, the channel protection layer 502 may, for example, improve device reliability and improve manufacturing yields. For example, hydrogen that diffuses to the semiconductor channels 116 may shift threshold voltages of the plurality of vertical TFTs 104 in uncontrolled ways that degrade reliability of the plurality of vertical TFTs 104. Hence, by blocking this hydrogen, the channel protection layer 502 improves device reliability.

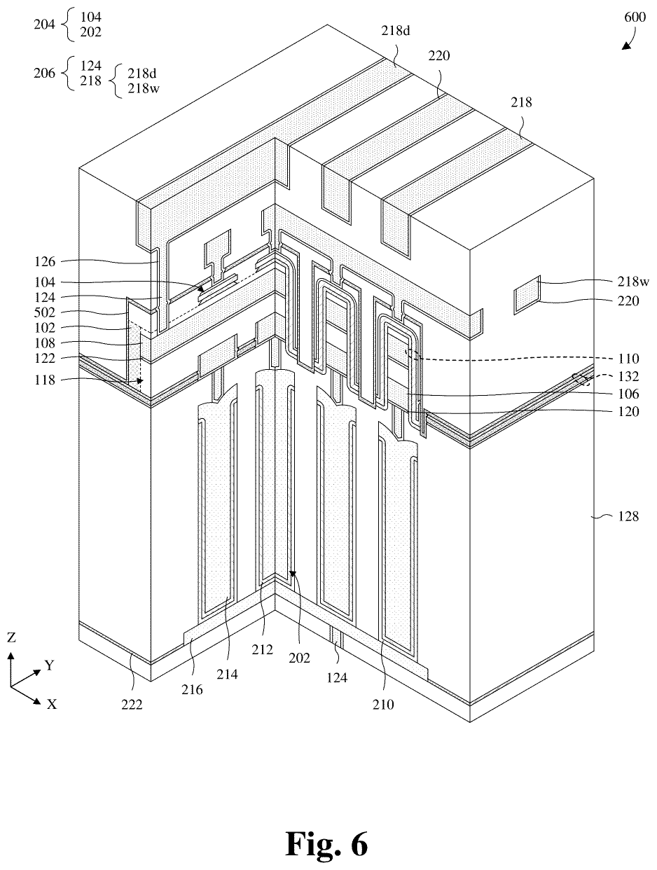

With reference to FIG. 6, a perspective view 600 of some alternative embodiments of the semiconductor structure of FIGS. 5A-5D is provided in which portions of the semiconductor structure are cut away and in which the plurality of film stacks 110 have different cross-sectional profiles similar to those in FIG. 4. The semiconductor structure is the same as that illustrated and described with regard to FIGS. 5A-5D, except for the different profiles, and the cut-away portion corresponds to the bottom-right quadrant demarcated by line D-D′ and line E-E′ in FIG. 5B.

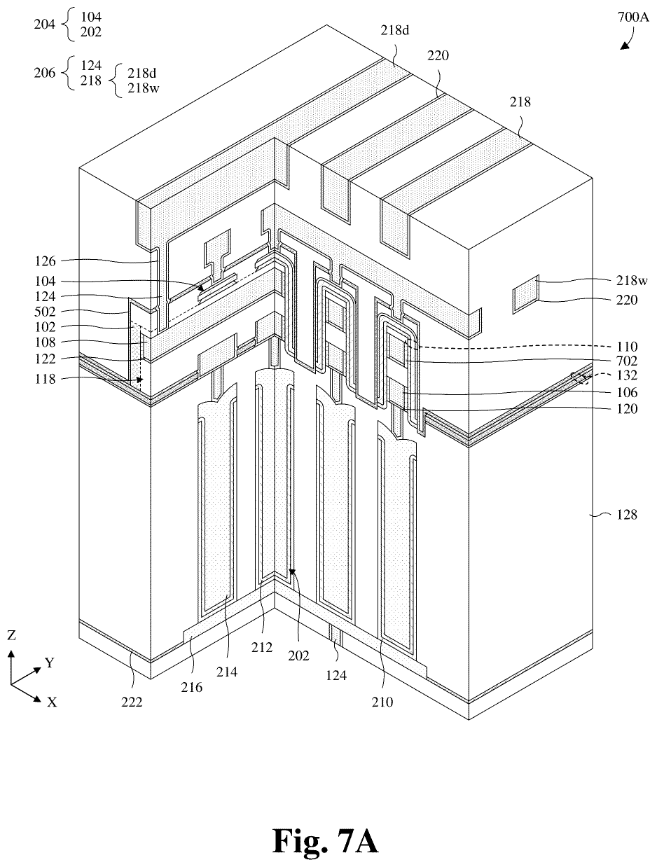

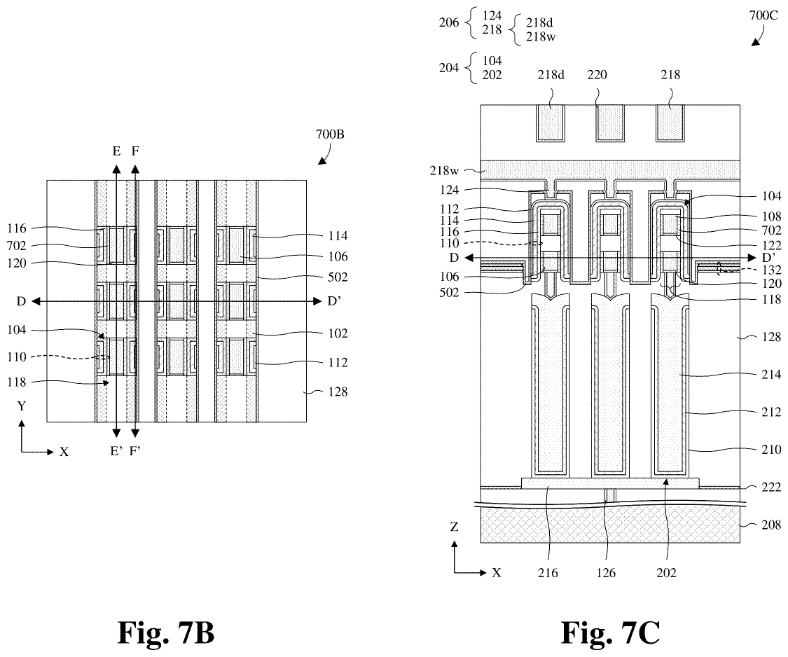

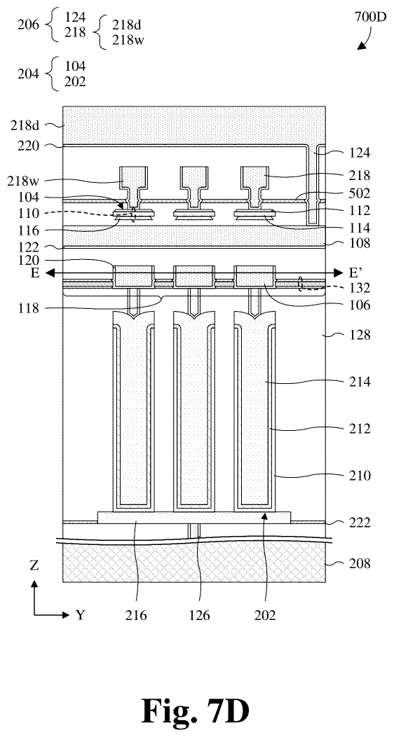

With reference to FIGS. 7A-7D, various views 700A-700D of some alternative embodiments of the semiconductor structure of FIGS. 2A-2F are provided in which the semiconductor structure comprises a channel protection layer 502 and a plurality of source/drain liners 702. FIG. 7A corresponds to a perspective view 700A in which portions have been cut away, said portions corresponding to the bottom-right quadrant demarcated by line D-D′ and line E-E′ in FIG. 7B. FIGS. 7C and 7D correspond to cross-sectional views 700C, 700D respectively along lines D-D′ and E-E′ in FIG. 7B, and FIG. 7B corresponds to a top-sectional view 700B along lines D-D′ and E-E′ respectively in FIGS. 7C and 7D.

The channel protection layer 502 surrounds the plurality of vertical TFTs 104, as described above, to protect the plurality of vertical TFTs from hydrogen and other errant particles. This, in turn, improves reliability of the plurality of vertical TFTs 104 and increases manufacturing yields of the semiconductor structure.

The plurality of source/drain liners 702 are individual to and respectively on sidewalls of the plurality of source electrodes 106 and sidewalls of the plurality of drain electrodes 108 to separate the sidewalls from the plurality of film stacks 110. The plurality of source/drain liners 702 are configured to reduce contact resistance from the plurality of source electrodes 106 and the plurality of drain electrodes 108 respectively to the semiconductor channels 116 by creating an ohmic-like contact. The plurality of source/drain liners 702 are a different semiconductor material than the semiconductor channels 116 and may, for example, be or comprise indium gallium zinc oxide (e.g., IGZO), indium oxide (e.g., InO), zinc oxide (e.g., ZnO), indium zinc oxide (e.g., InZnO), indium tungsten oxide (e.g., IWO), tin oxide (e.g., ZnO), some other suitable semiconductor material, or any combination of the foregoing.

In some embodiments, the ohmic-like contact results from the plurality of source/drain liners 702 having a small width that promotes carrier tunneling through the plurality of source/drain liners 702. For example, the plurality of source/drain liners 702 may have widths of 1-10 nanometers, 10-20 nanometers, or some other suitable value.

In some embodiments, the plurality of source/drain liners 702 decrease the source/drain contact resistances (e.g., R_{csd}) of the plurality of TFTs 104 to about 0.4 percent, 0.1 to 1 percent, or 1 to 10 percent of what they would otherwise be. In some embodiments, threshold voltages (e.g., Vₜ) of the plurality of vertical TFTs 104 are the same with and without the plurality of source/drain liners 702. In some embodiments, the plurality of source/drain liners 702 increase the ON currents (e.g., Iₒₙ) of the plurality of vertical TFTs 104 to about 135.3 percent, 100 to 125 percent, or 125 to 150 percent of what they would otherwise be. In some embodiments, the plurality of source/drain liners 702 decrease the subthreshold swings (e.g., SS) of the plurality of vertical TFTs 104 to about 85 percent, 85-95 percent, or 75 to 85 percent of what they would otherwise be. Notwithstanding the specific values and ranges enumerated above for source/drain contact resistances, threshold voltages, ON currents, and subthreshold swings, other suitable values for these parameters are amenable.

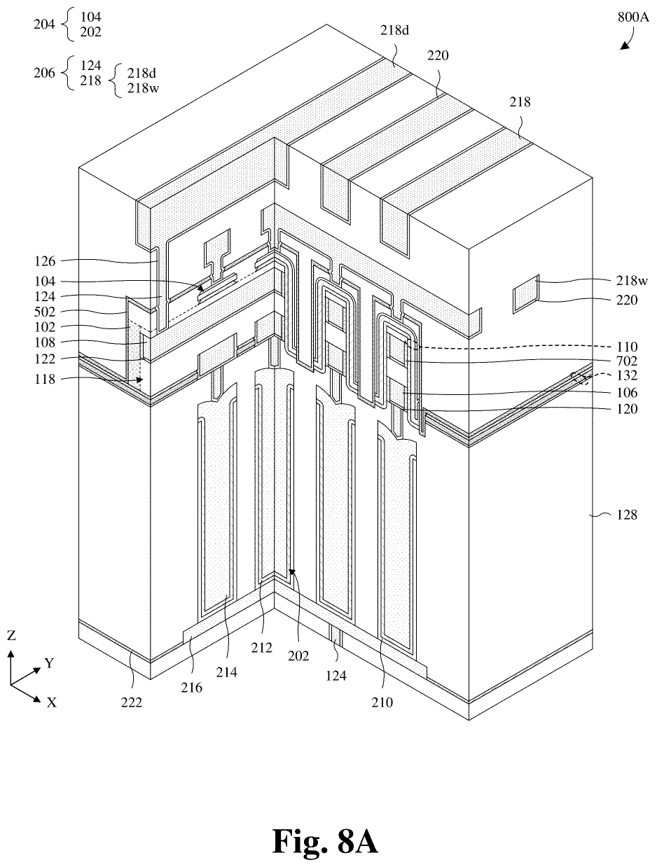

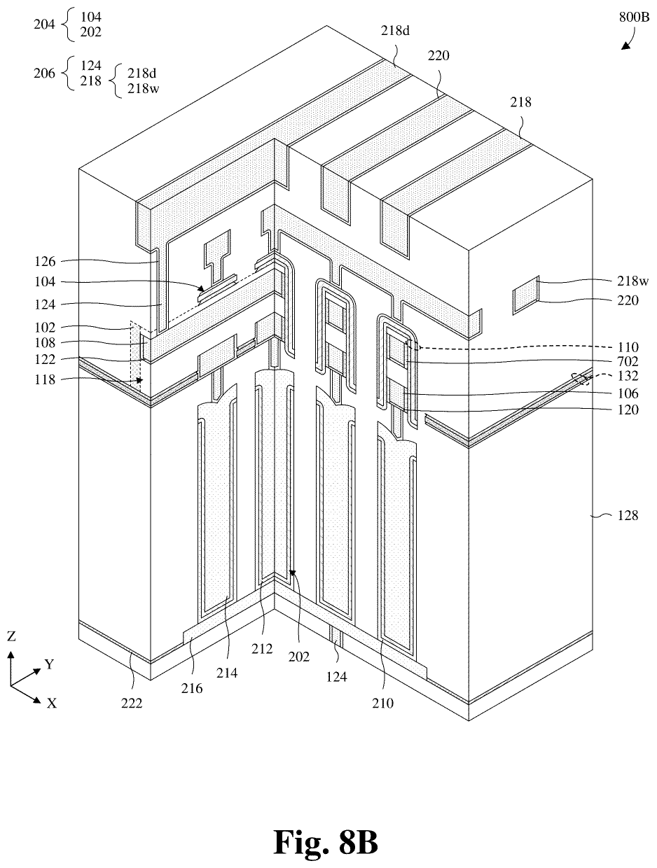

With reference to FIGS. 8A and 8B, perspective views 800A, 800B of various different alternative embodiments of the semiconductor structure of FIGS. 7A-7D are provided in which portions of the semiconductor structure are cut away. The semiconductor structure is the same as that illustrated and described with regard to FIGS. 7A-7D, except as below, and the cut-away portion corresponds to the bottom-right quadrant demarcated by line D-D′ and line E-E′ in FIG. 7B. In FIG. 8A, the plurality of film stacks 110 have different cross-sectional profiles similar to those in FIG. 4. In FIG. 8B, the channel protection layer 502 is omitted.

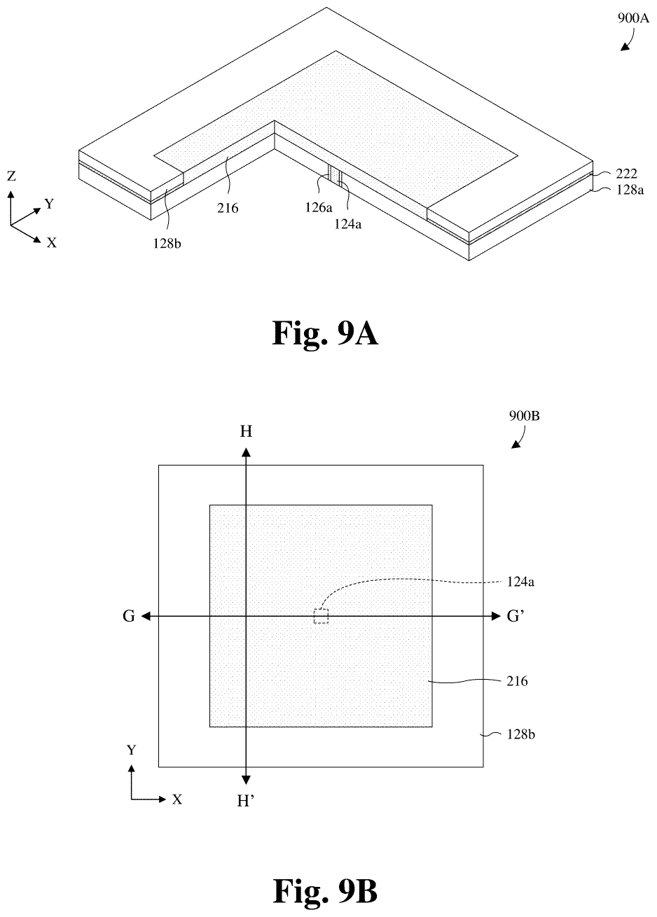

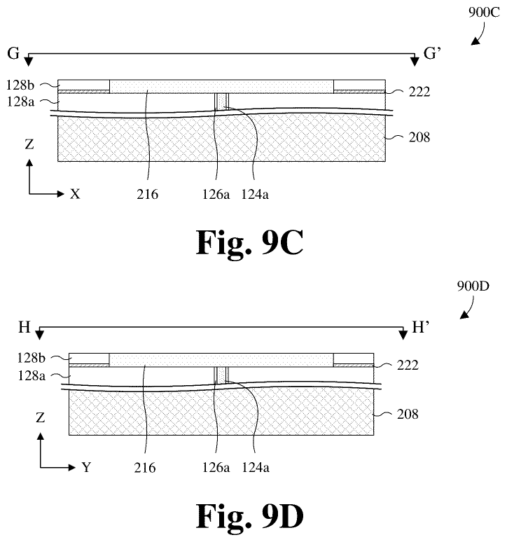

With reference to FIGS. 9A-9D to FIGS. 27A-27D, a series of views of some embodiments of a method for forming a semiconductor structure comprising a plurality of vertical TFTs and a plurality of isolation walls between the vertical TFTs is provided. The semiconductor structure may, for example, correspond to the semiconductor structure of FIG. 4 or some other suitable semiconductor structure.

Figures labeled with a suffix of A correspond to perspective views in which portions have been cut away, said portions corresponding to the bottom-right quadrant demarcated by lines G-G′ and H-H′ in like-numbered figure with a suffix of B. Figures labeled with suffixes of C-F correspond to cross-sectional views respectively along lines G-G′, H-H′, I-I′, and J-J′ in a like-numbered figure with a suffix of B. Figures labeled with a suffix of B correspond to top-down views for the structures represented by like-numbered figures with suffixes of A and C-F. Note that not all like-numbered sets of figures include figures labeled with suffixes of E and F.

Focusing on views 900A-900D of FIGS. 9A-9D, a BEOL interconnect structure is partially formed over a substrate 208. However, for ease of illustration, details of the BEOL interconnect structure are omitted and only via 124a of the BEOL interconnect structure is shown. There may be additional vias and/or wires outside the views 900A-900D of FIGS. 9A-9D. Also, for ease of illustration, the substrate 208 is omitted from the perspective view 900A of FIG. 9A and subsequent perspective views. Via 124a is in a dielectric structure, which includes ILD layer 128a and ILD layer 128b. Further, via 124a comprise a via body and via liner 126a lining the via body. Note that for ease of illustration, the via body is labeled as via 124a. ILD layer 128a underlies etch stop layer 222, which underlies ILD layer 128b.

After partially forming the BEOL interconnect structure, a bottom-electrode pad 216 is formed atop via 124a, inset into ILD layer 128b and etch stop layer 222. As a result, via 124a electrically couples the bottom-electrode pad 216 to a remainder of the BEOL interconnect structure. In some embodiments, the bottom-electrode pad 216 may be regarded as part of and/or as an extension of the BEOL interconnect structure.

Formation of the bottom-electrode pad 216 may, for example, include: patterning ILD layer 128b and etch stop layer 222 to form an opening, which has a layout of the bottom-electrode pad 216 and which exposes via 124a; depositing a conductive layer overlying ILD layer 128b and filling the opening; and performing a planarization into the conductive layer to remove the conductive layer from atop ILD layer 128b. The patterning may, for example, include etching that uses etch stop layer 222 as an etch stop.

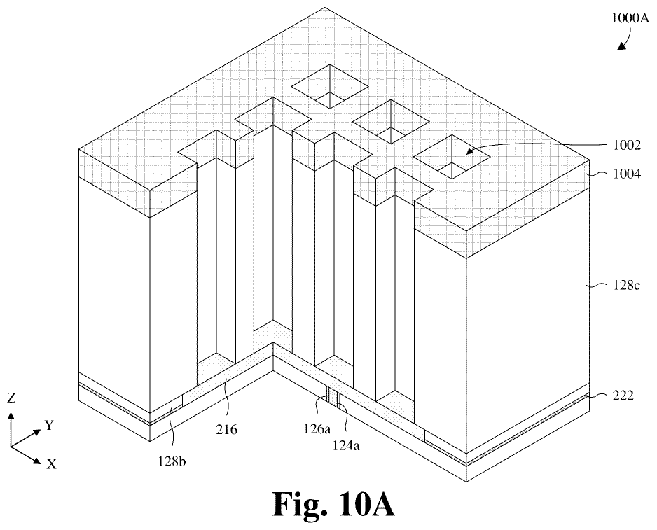

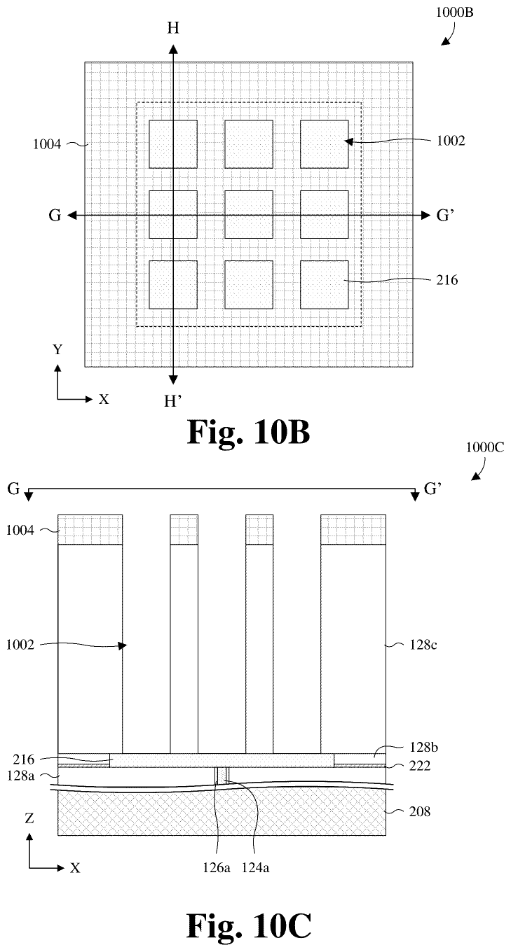

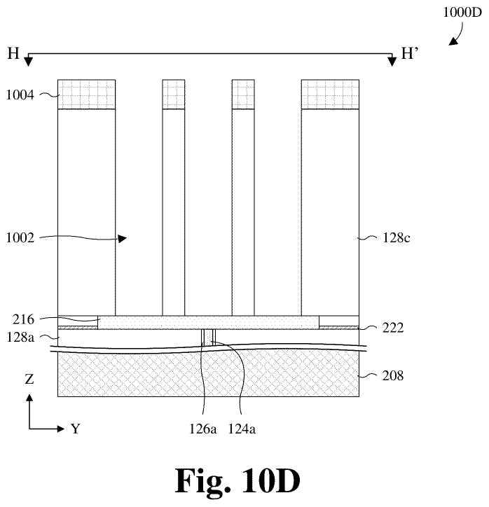

Focusing on views 1000A-1000D of FIGS. 10A-10D, ILD layer 128c is deposited over the bottom-electrode pad 216 and ILD layer 128b. Further, ILD layer 128c is patterned to form a plurality of openings 1002. The plurality of openings 1002 extend through ILD layer 128c to the bottom-electrode pad 216. Further, the plurality of openings 1002 are in a plurality of rows and a plurality of columns. The plurality of rows extend in an X direction and total three, whereas the plurality of columns extend in a Y direction and total three. In alternative embodiments, more or less rows and/or more or less columns may be formed.

In some embodiments, a process for forming the plurality of openings 1002 comprises a photolithography/etching process. For example, a mask 1004 is formed over ILD layer 128c using photolithography and then an etch is performed into ILD layer 128c with the mask 1004 in place. The mask 1004 may, for example, be or comprise a photoresist mask, a hard mask, some other suitable mask, or any combination of the foregoing. Further, after the etching, the mask 1004 may be removed. In alternative embodiments, the plurality of openings 1002 may be formed by some other suitable process.

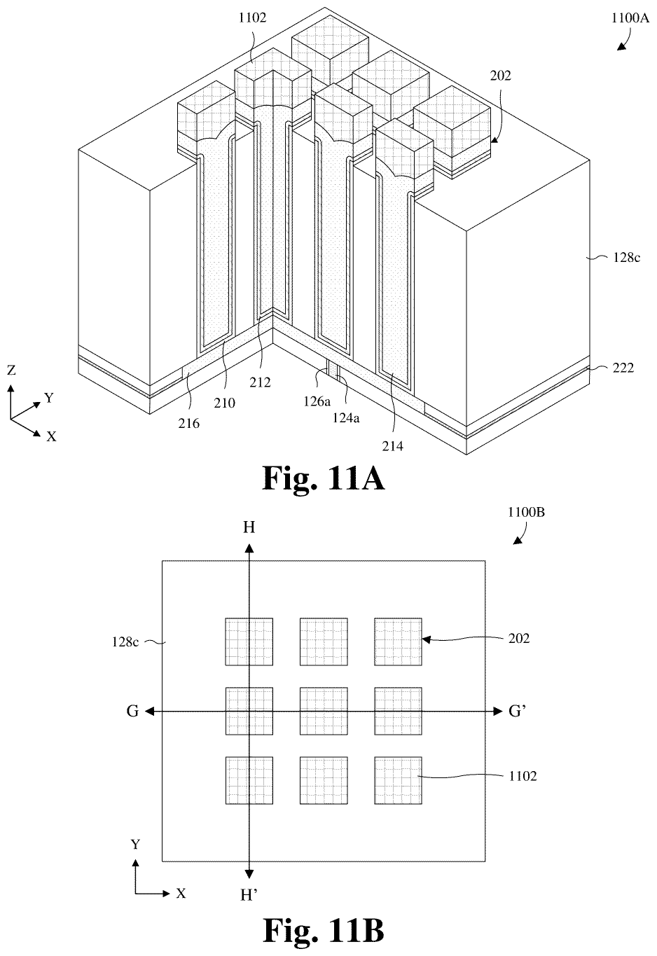

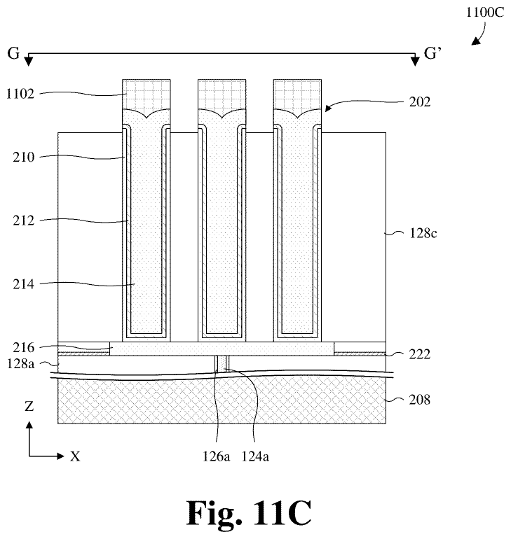

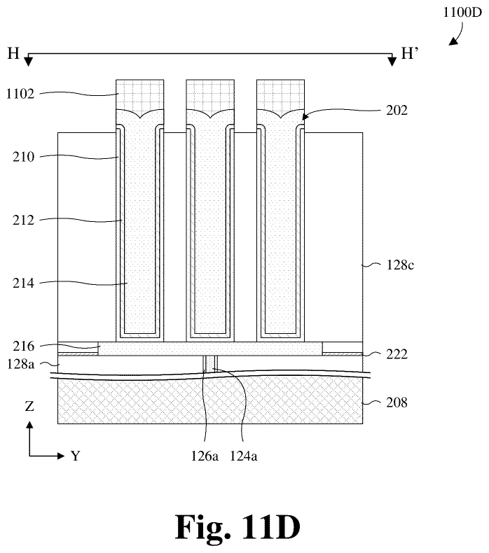

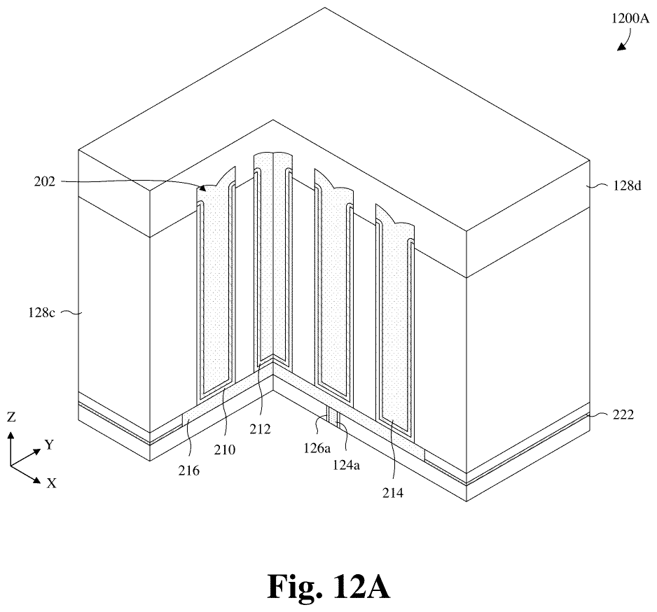

Focusing on views 1100A-1100D of FIGS. 11A-11D, a plurality of storage structures 202 are formed respectively in the plurality of openings 1002. The plurality of storage structures 202 comprise individual bottom electrodes 210, individual insulators 212, and individual top electrodes 214. The bottom electrodes 210 overlie and are electrically coupled to the bottom-electrode pad 216, which is common to the bottom electrodes 210. The insulators 212 respectively overly and are recessed into the bottom electrodes 210, and the top electrodes 214 respectively overly and are recessed into the insulators 212.

In some embodiments, formation of the plurality of storage structures 202 comprises: depositing a multi-layer film overlying ILD layer 128c; and patterning the multi-layer film into the plurality of storage structures 202. The multi-layer film comprises a first conductive layer corresponding to the bottom electrodes 210, a dielectric layer overlying the first conductive layer and corresponding to the insulators 212, and a second conductive layer overlying the dielectric layer and corresponding to the top electrodes 214. The patterning may, for example, be performed by a photolithography/etching process. For example, a mask 1102 may be formed over the multi-layer film by or using photolithography and then an etch may be performed into the multi-layer film with the mask 1102 in place. Further, after the etching, the mask 1102 may be removed. In other embodiments, the plurality of storage structures 202 may be formed by some other suitable process.

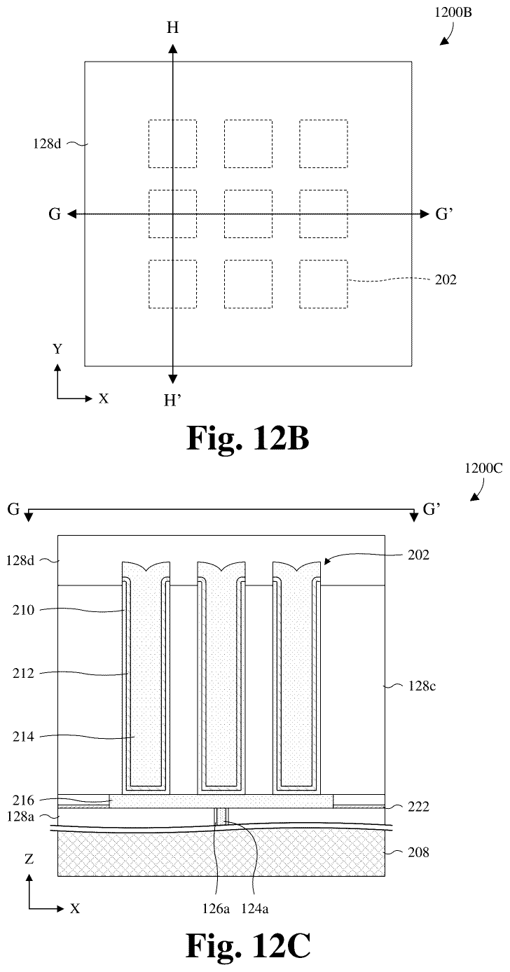

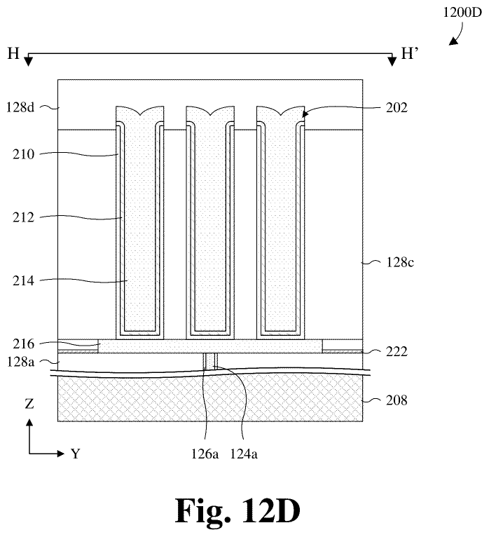

Focusing on views 1200A-1200D of FIGS. 12A-12D, ILD layer 128d is deposited over the plurality of storage structures 202. Further, a planarization is performed into a top surface of ILD layer 128d to flatten the top surface of ILD layer 128d.

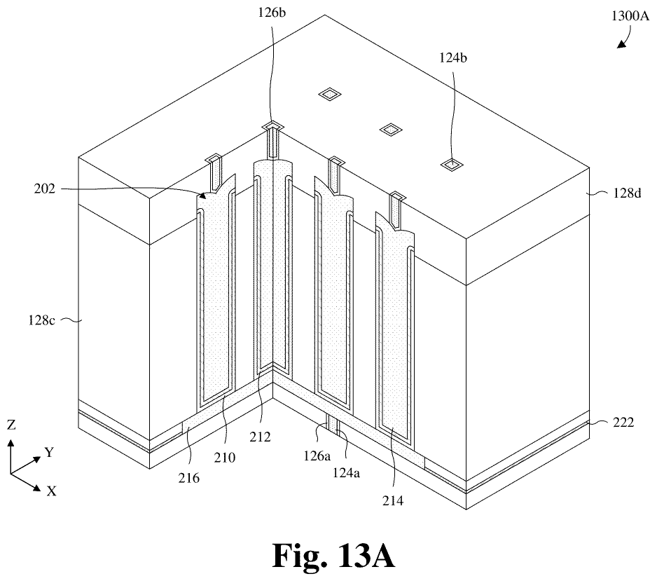

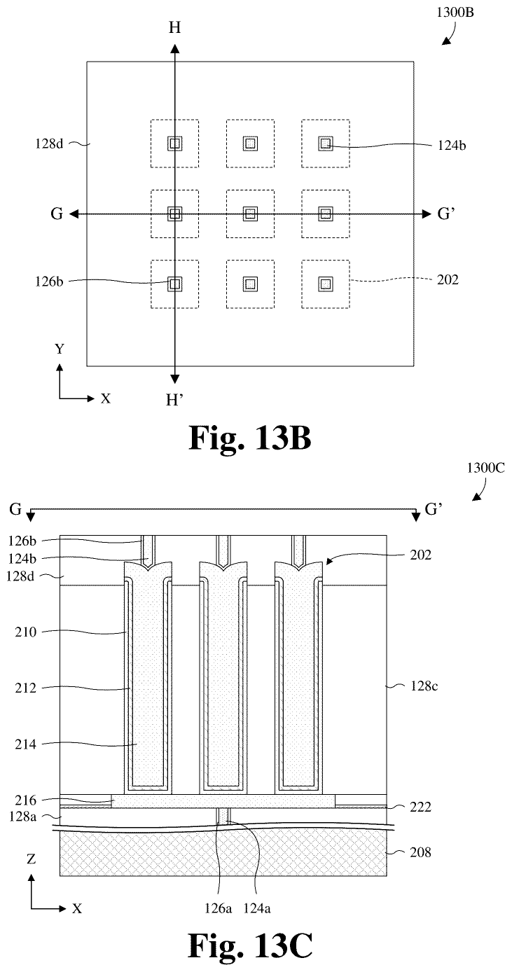

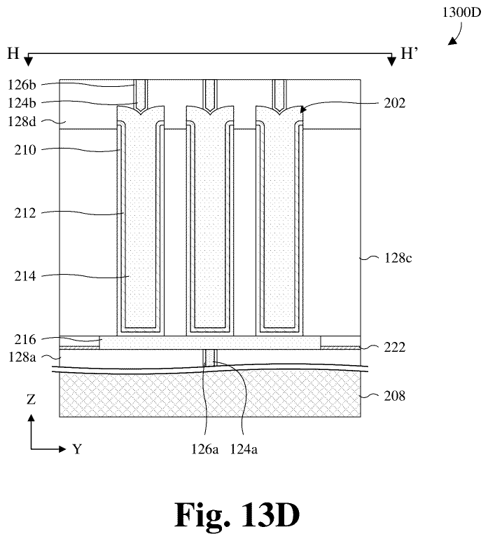

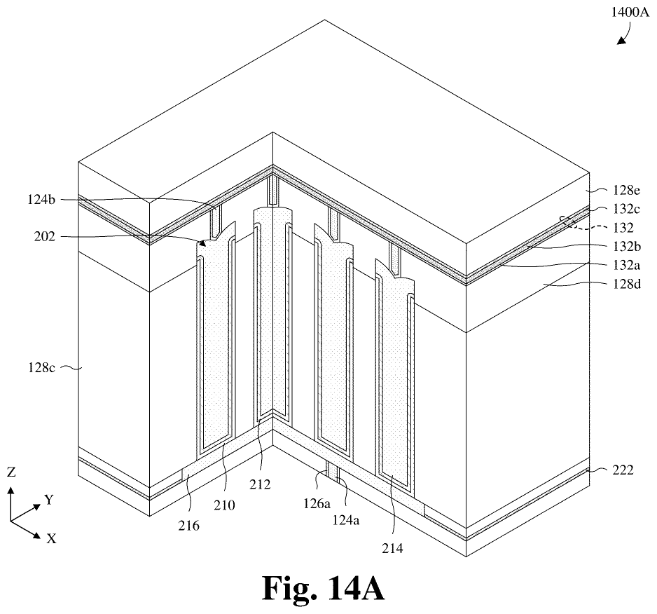

Focusing on views 1300A-1300D of FIGS. 13A-13D, vias 124b are formed extending through ILD layer 128d respectively to the top electrodes 214 of the storage structures 202. Vias 124b are individual to the top electrodes 214 and comprise individual via bodies and individual via liners 126b lining the via bodies. Note that for ease of illustration, the via bodies are labeled as vias 124b.

A process for forming vias 124b may, for example, comprise: patterning ILD layer 128d to form a plurality of openings exposing the top electrodes 214; depositing a conductive liner layer lining the openings; depositing a conductive body layer filing the openings and overlying the conductive liner layer; and performing a planarization into the conductive liner layer and the conductive body layer to expose a top surface of ILD layer 128d. In alternative embodiments, vias 124b may be formed by some other suitable process.

For ease of illustration and for drawing compactness, portions of the semiconductor structure below vias 124b are hereafter omitted from drawings labeled with suffixes of C-F. These omitted portions are as illustrated and described in FIGS. 13C and 13D, as well as in the like number figures labeled with a suffix of A.

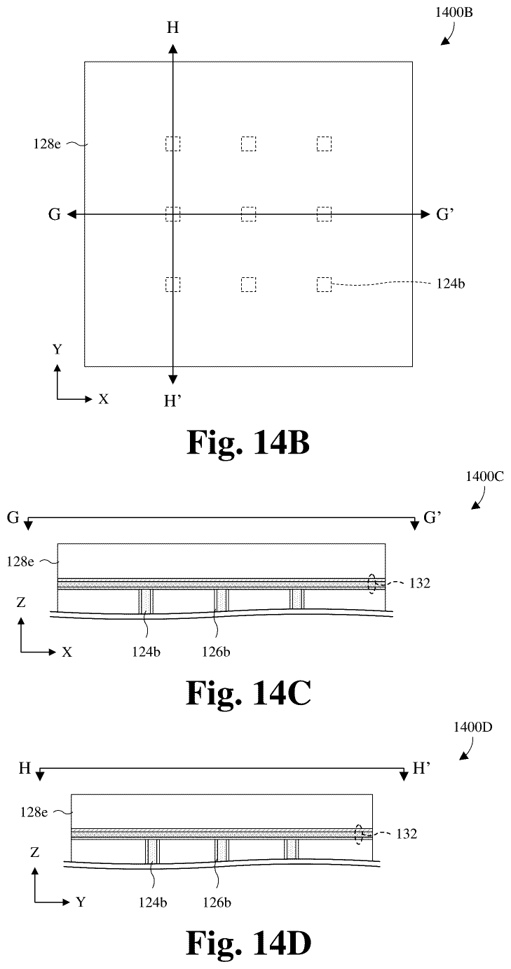

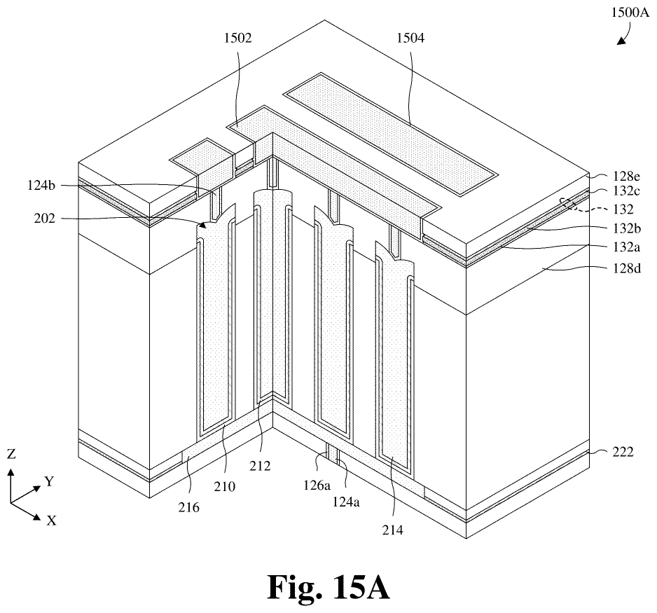

Focusing on views 1400A-1400D of FIGS. 14A-14D, etch stop layer 132 is deposited over ILD layer 128d and vias 124b. Further, ILD layer 128e is deposited over etch stop layer 132. Etch stop layer 132 comprises a first layer 132a, a second layer 132b over the first layer 132a, and a third layer 132c over the second layer 132b. Alternatively, etch stop layer 132 may comprise more or less layers. For example, any two of the layers may be omitted, such that etch stop layer 132 and the remaining layer are one and the same.

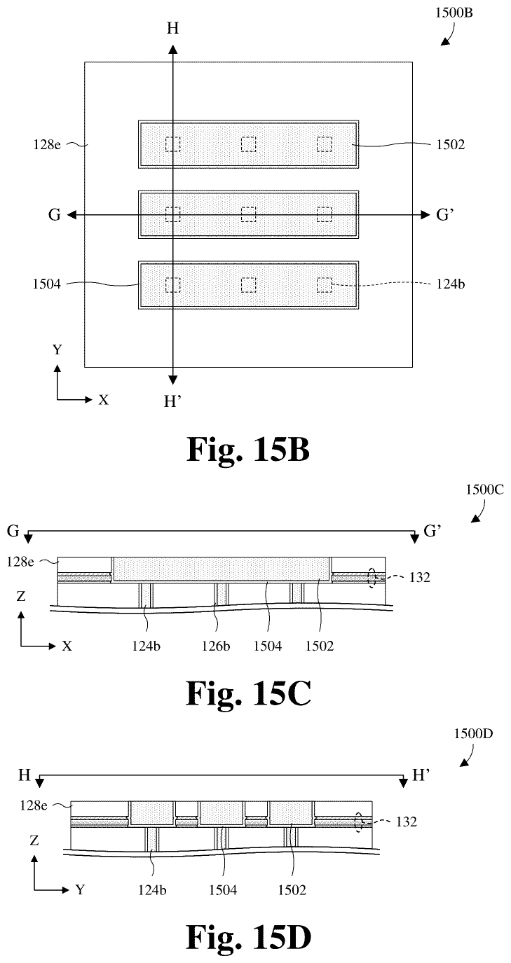

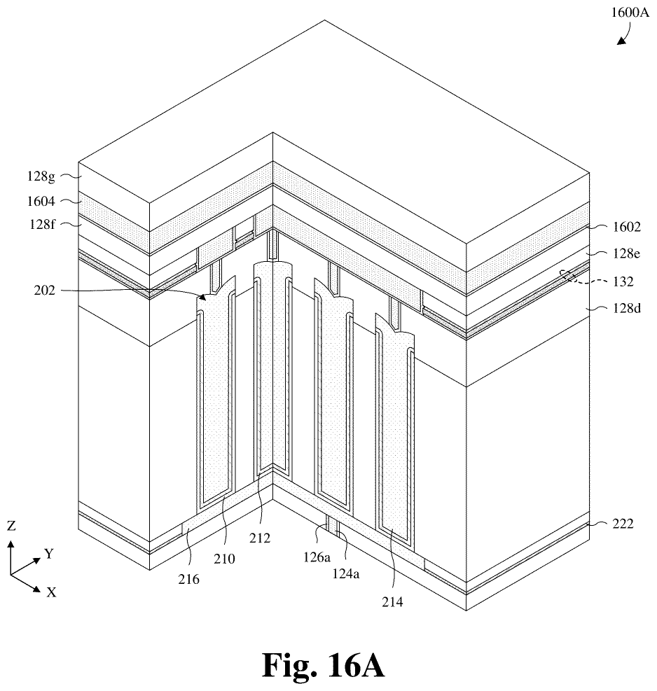

Focusing on views 1500A-1500D of FIGS. 15A-15D, a plurality of conductive lines 1502 are formed respectively on vias 124b, inset into ILD layer 128e and etch stop layer 132. Further, the plurality of conductive lines 1502 are individual to the rows of storage structures and each overlies and electrically couples to top electrodes of storages structures in the corresponding row through vias 124b. Hence, the plurality of conductive lines 1502 are laterally elongated in the X direction.

The plurality of conductive lines 1502 comprise individual conductive bodies and individual conductive liners 1504. Note that for ease of illustration, the conductive bodies are labeled as the plurality of conductive lines 1502. The conductive liners 1504 extend along bottom surfaces of the conductive bodies and along sidewalls of the conductive bodies. The conductive liners 1504 may, for example, be configured to prevent outward diffusion of material from the conductive bodies and/or to increase adhesion of the conductive bodies to surrounding structure. In alternative embodiments, the conductive liners 1504 are omitted.

A process for forming the plurality of conductive lines 1502 may, for example, comprise: patterning ILD layer 128e and etch stop layer 132 to form openings, which have layouts of the plurality of conductive lines 1502 and which expose vias 124b; depositing a conductive liner layer lining the openings; depositing a conductive body layer filling the openings over the conductive liner layer; and performing a planarization into the conductive liner layer and the conductive body layer to expose a top surface of ILD layer 128e. The patterning may, for example, be or comprise a photolithography/etching process or some other suitable patterning process. Further, the patterning may, for example, include etching into ILD layer 128e that uses etch stop layer 132 as an etch stop. In alternative embodiments, the plurality of conductive lines 1502 are formed by some other suitable process.

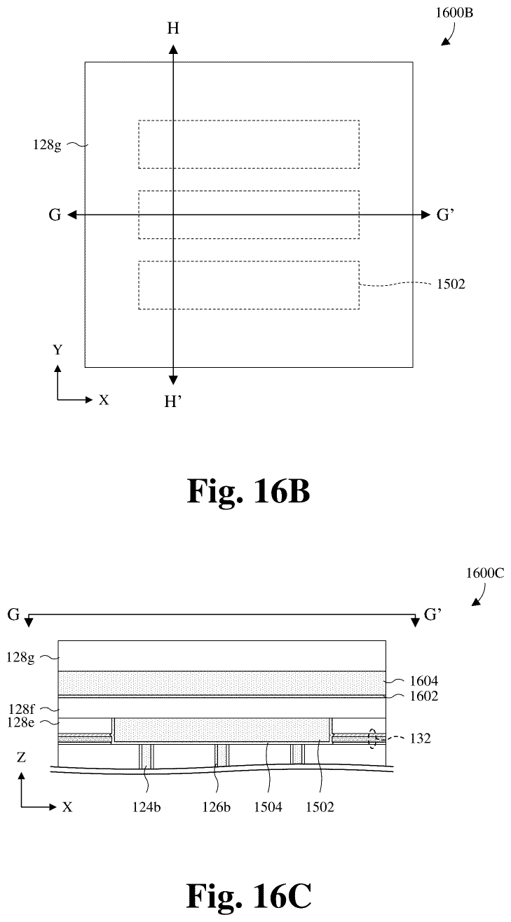

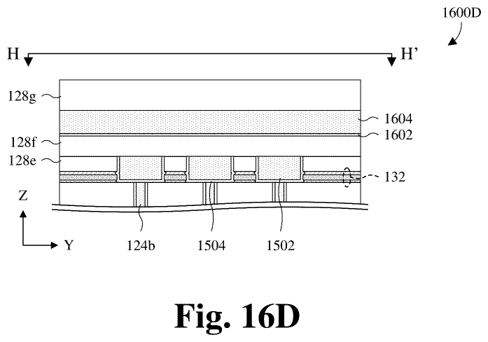

Focusing on views 1600A-1600D of FIGS. 16A-16D, ILD layer 128f, a conductive liner layer 1602, a conductive layer 1604, and ILD layer 128g are deposited over the plurality of conductive lines 1502 and ILD layer 128e. ILD layer 128f is deposited first and then the conductive liner layer 1602 is deposited over ILD layer 128f. Further, the conductive layer 1604 is deposited over the conductive liner layer 1602, and ILD layer 128g is deposited over conductive layer 1604. As seen hereafter, a thickness of ILD layer 128f defines a gate length of vertical TFTs being formed.

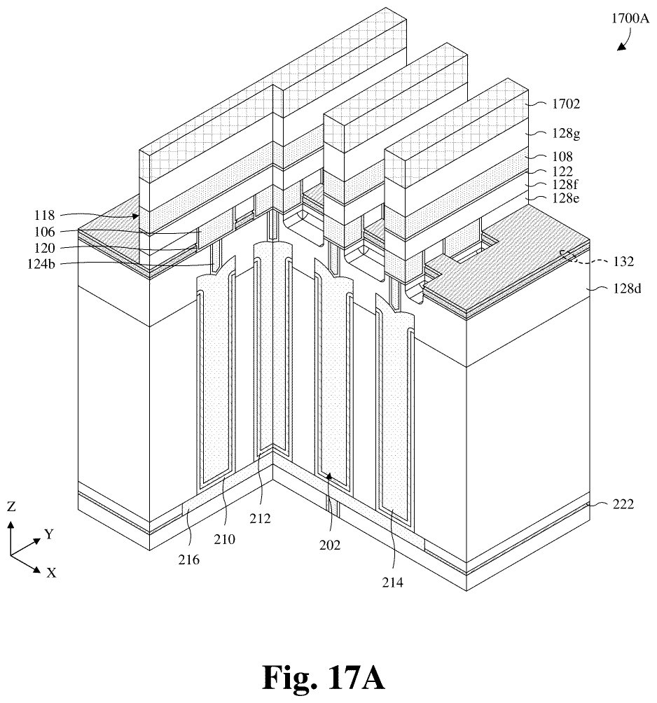

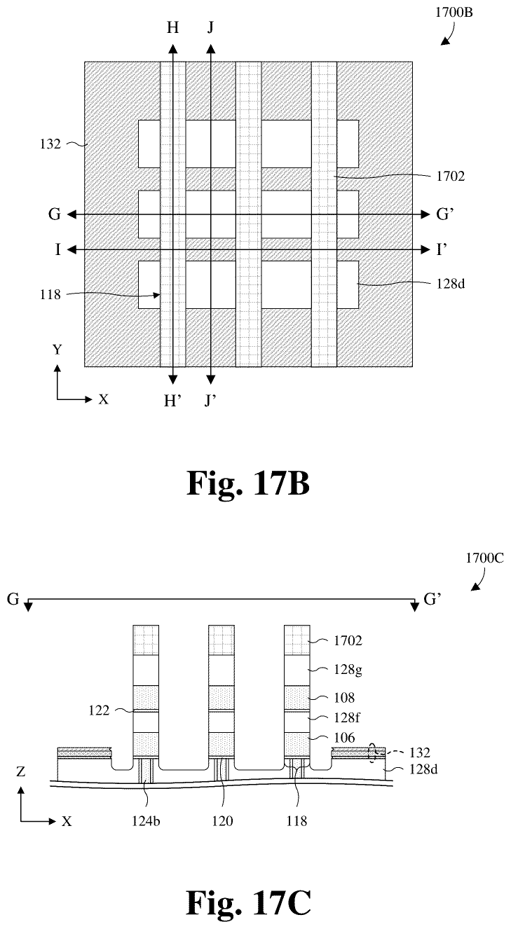

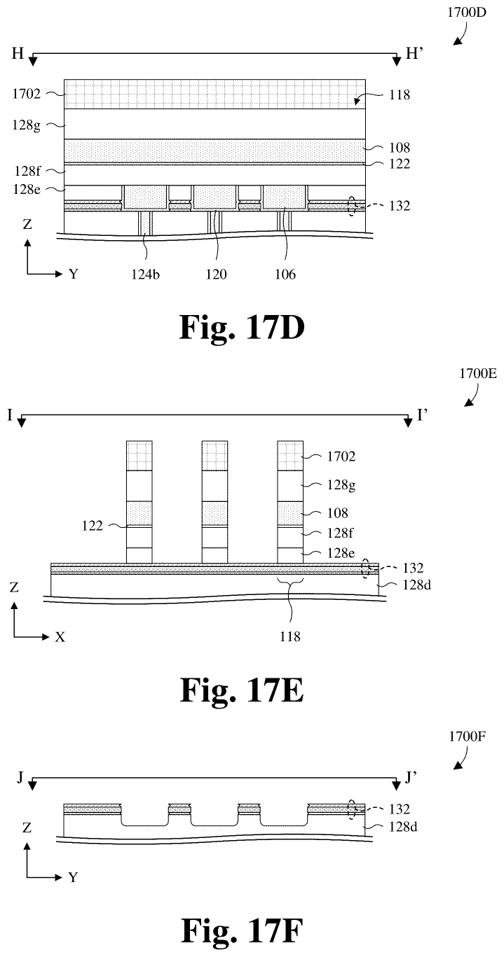

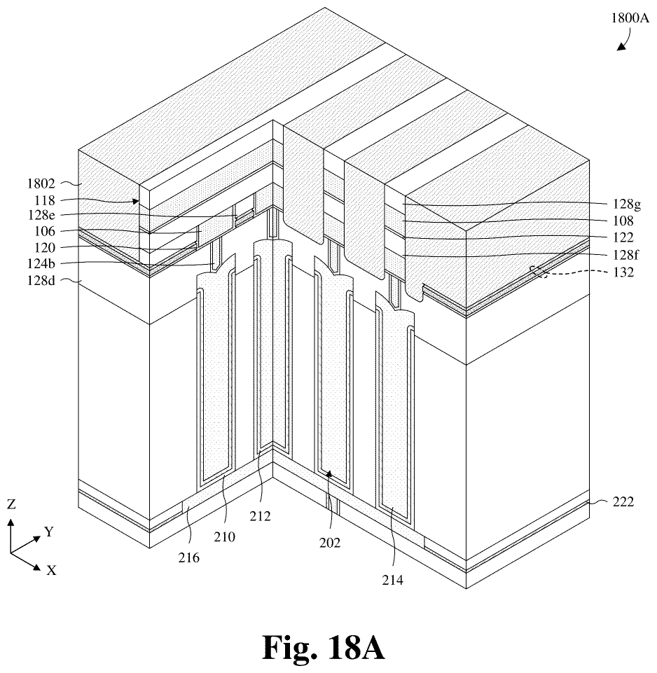

Focusing on views 1700A-1700F of FIGS. 17A-17F, ILD layers 128d-128g, the conductive layer 1604, conductive liner layer 1602, the plurality of conductive lines 1502 are patterned. The patterning forms a plurality of fin-shaped structures 118 elongated in a Y direction and individual to and respectively overlying the columns of storage structures. Further, the patterning forms a plurality of drain electrodes 108 and a plurality of source electrodes 106 in the plurality of fin-shaped structures 118.

The plurality of source electrodes 106 comprise individual source bodies and individual source liners 120 lining the source bodies. Note that for ease of illustration, the source bodies are labeled as the plurality of source electrodes 106. The plurality of source electrodes 106 are individual to and respectively overlie the plurality of storage structures 202. Hence, the plurality of source electrodes 106 are in a plurality of rows and a plurality of columns. Further, the plurality of source electrodes 106 are electrically coupled respectively to the top electrodes 214 of the plurality of storage structures 202 by the plurality of vias 124b.

The plurality of drain electrodes 108 comprise individual drain bodies and individual drain liners 1202 lining the drain bodies. Note that for ease of illustration, the drain bodies are labeled as the plurality of drain electrodes 108. The plurality of drain electrodes 108 are individual to the plurality of columns and each overlies and is spaced from source electrodes in the corresponding column. Such spacing is defined by a thickness of ILD layer 128f and controls a gate length for the vertical TFTs being formed.

A process for performing the patterning may, for example, comprise: forming a mask 1702 over ILD layer 128g using photolithography; performing an etch into ILD layers 128d-128g, the conductive layer 1604, conductive liner layer 1602, and the plurality of conductive lines 1502 with the mask 1702 in place; and removing the mask 1702. The mask 1702 may, for example, be or comprise a photoresist mask, a hard mask, or some other suitable type. Further, etch stop layer 132 may, for example, serve as an etch stop the etch. In other embodiments, the patterning is performed by some other suitable process.

Because the plurality of drain electrode 108 and the plurality of source electrodes 106 are formed by a common etch with a common mask, the plurality of drain electrodes 108 and the plurality of source electrodes 106 are formed self-aligned with each other. As a result, misalignment therebetween is reduced. This may reduce misalignment-induced degradation of electrical properties of the vertical TFTs being formed, as well as improve uniformity of the electrical properties and manufacturing yields.

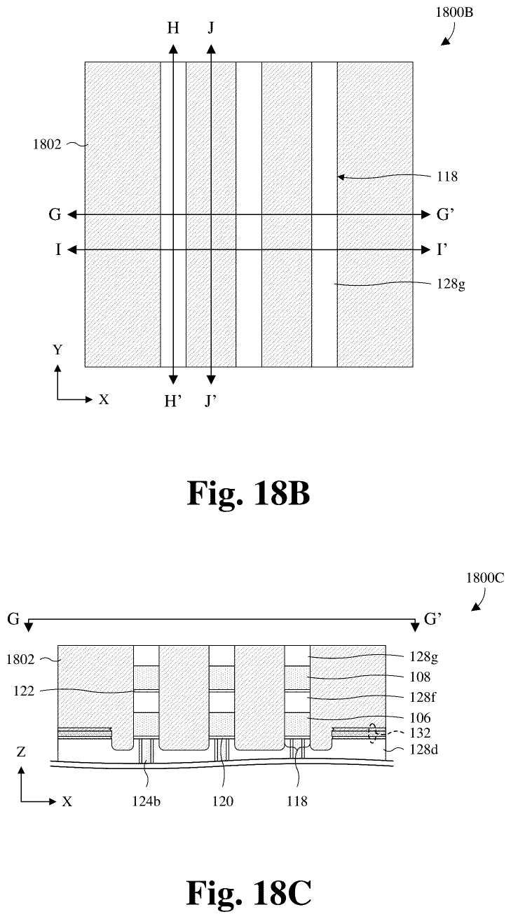

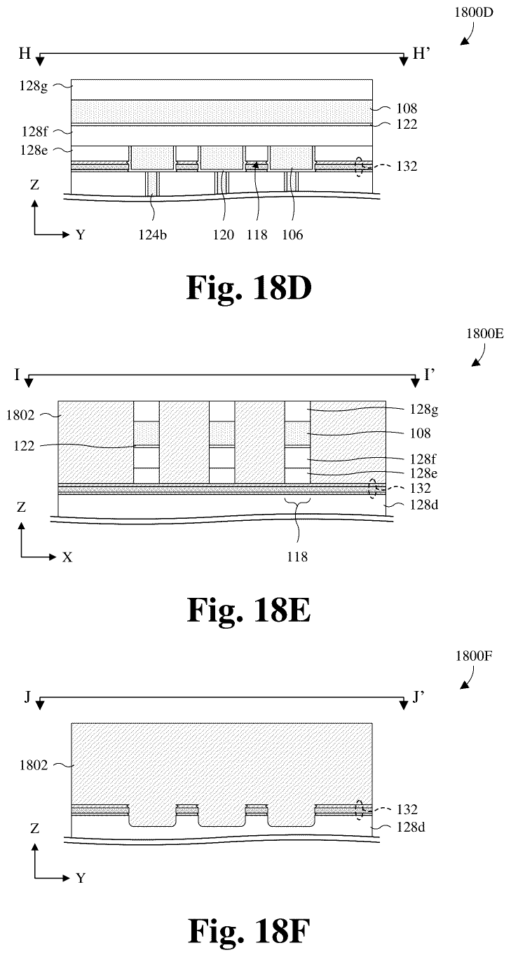

Focusing on views 1800A-1800F of FIGS. 18A-18F, a sacrificial layer 1802 is formed filling gaps between the fin-shaped structures 118. As seen hereafter, the sacrificial layer 1802 may also be known as a reverse patterning layer or the like. The sacrificial layer 1802 may, for example, be or comprise silicon nitride, amorphous silicon, low-temperature oxide, some other suitable material, or any combination of the foregoing.

A process for forming the sacrificial layer 1802 may, for example, comprise: depositing the sacrificial layer 1802 overlying the fin-shaped structures 118 and in the gaps between the fin-shaped structures 118; and performing a planarization into the sacrificial layer 1802 to clear the sacrificial layer from 1802 from top surfaces of the fin-shaped structures 118. In alternative embodiments, the sacrificial layer 1802 is formed by some other suitable process.

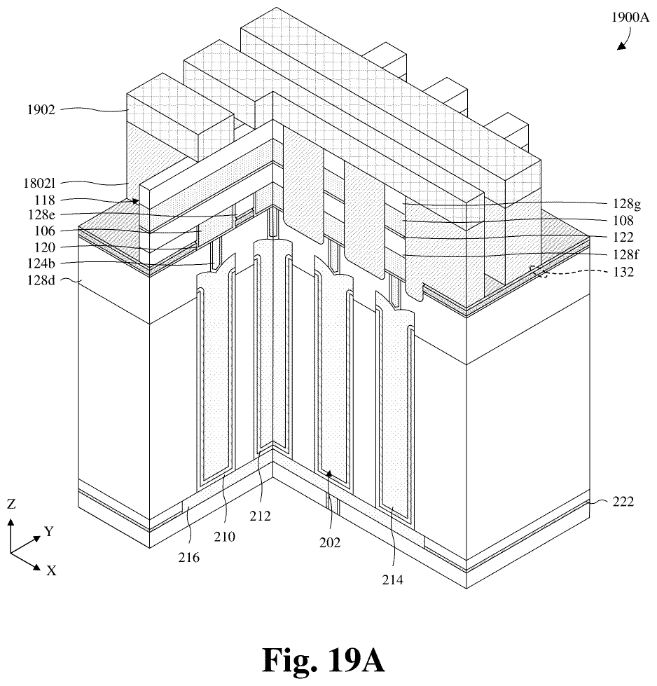

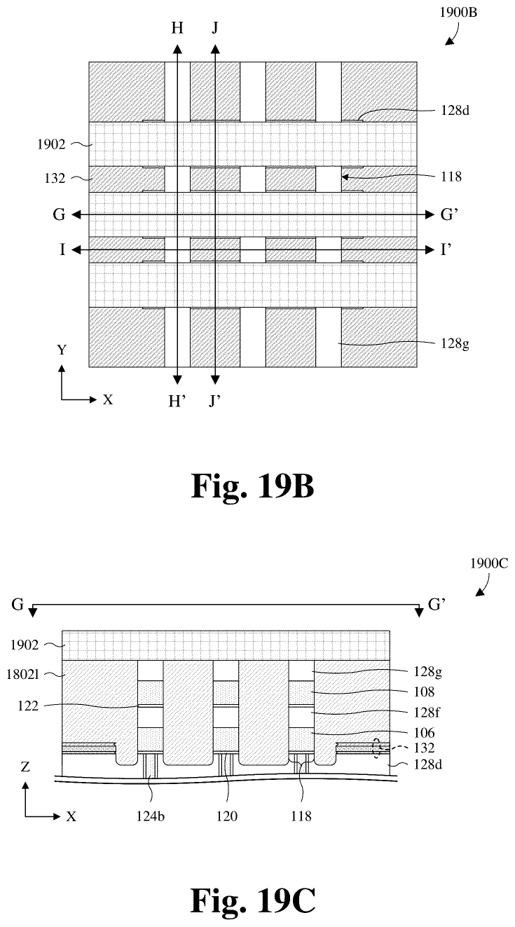

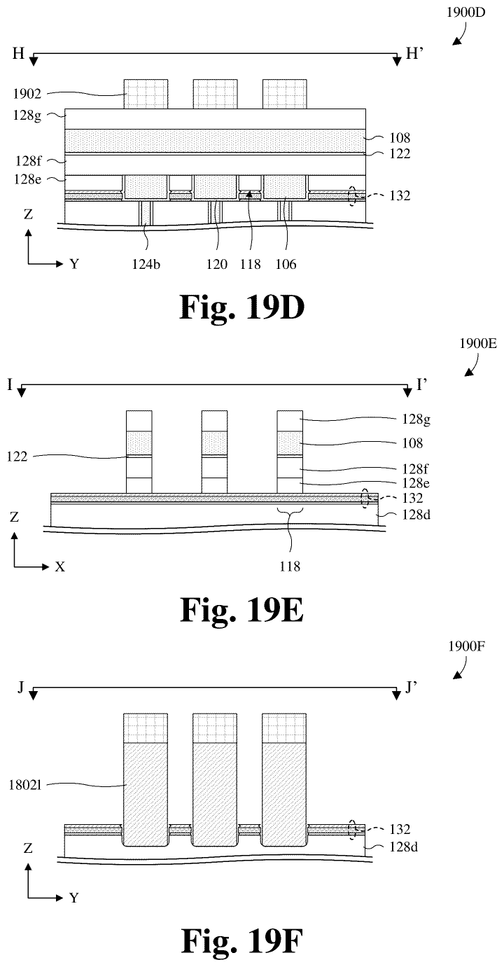

Focusing on views 1900A-1900F of FIGS. 19A-19F, the sacrificial layer 1802 is patterned to form a plurality of sacrificial lines 1802l, which are individual to and respectively elongated along the rows of source electrodes. As will be seen hereafter, the plurality of sacrificial lines 1802l and the fin-shaped structures 118 collectively have a reverse pattern of isolation walls being formed.

A process for performing the patterning may, for example, comprise: forming a mask 1902 over the sacrificial layer 1802 using photolithography; performing an etch into the sacrificial layer 1802 with the mask 1902 in place; and removing the mask 1902. The mask 1902 may, for example, be or comprise a photoresist mask, a hard mask, some other suitable type, or any combination of the foregoing. Further, etch stop layer 132 may, for example, serve as an etch stop for the etch. Alternatively, the patterning is performed by some other suitable process.

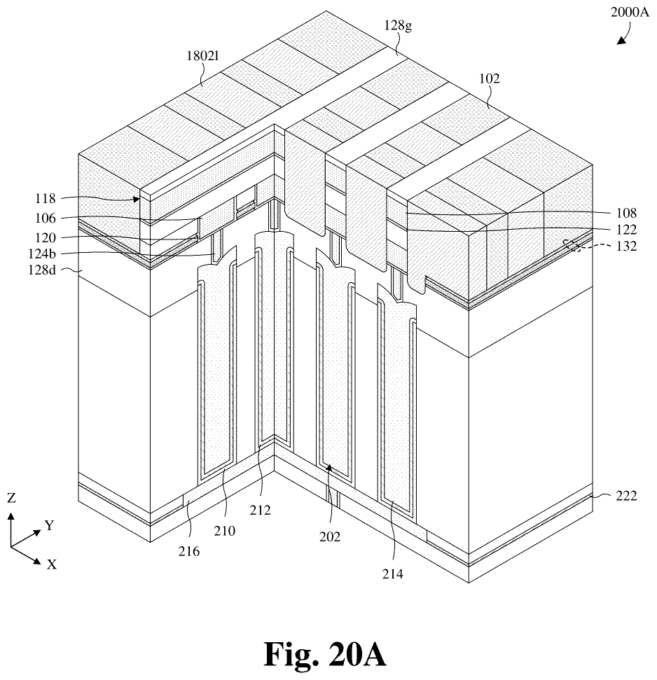

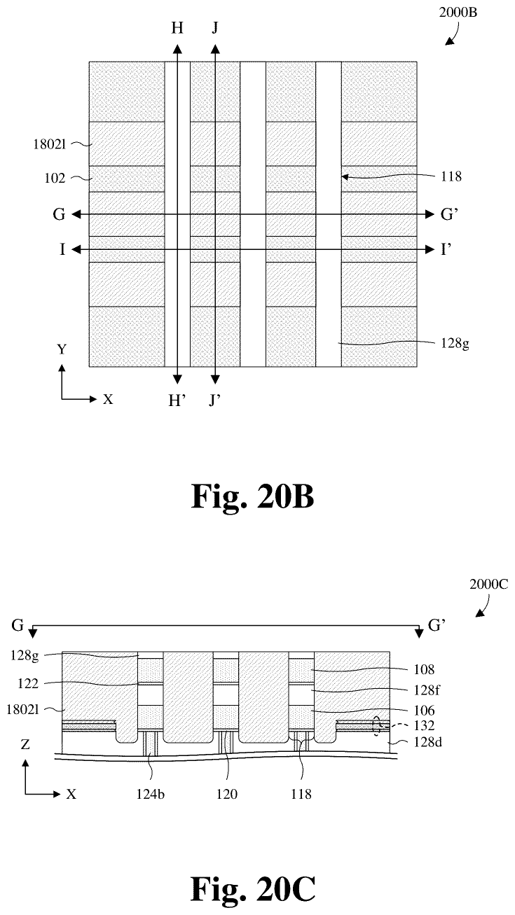

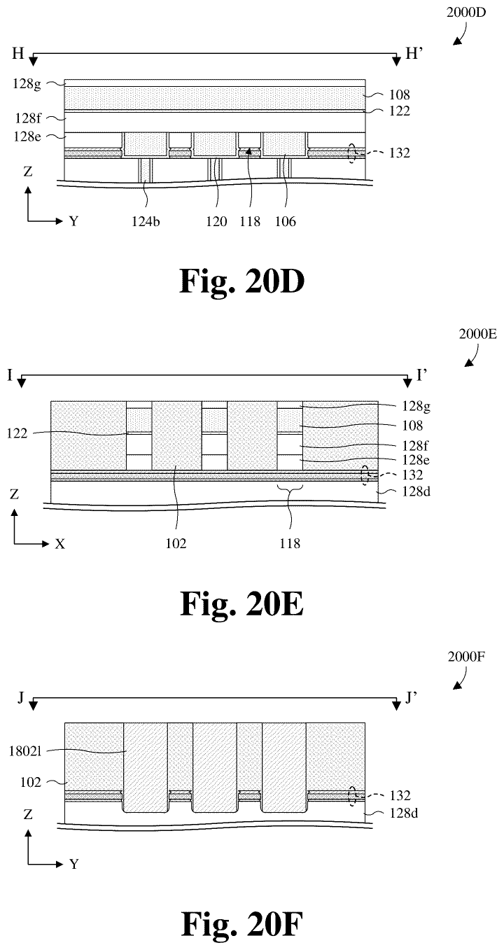

Focusing on views 2000A-2000F of FIGS. 20A-20F, a plurality of isolation walls 102 are formed filling gaps between the plurality of sacrificial lines 1802l and gaps between the plurality of fin-shaped structures 118. Accordingly, the plurality of isolation walls 102 collectively have a pattern that is the reverse of a pattern formed collectively by the plurality of sacrificial lines 1802l and the plurality of fin-shaped structures 118.

A process for forming the plurality of isolation walls 102 may, for example, comprise: depositing a dielectric layer covering the plurality of sacrificial lines 1802l and the plurality of fin-shaped structures 118 and filling the gaps between the plurality of sacrificial lines 1802l and between the plurality of fin-shaped structures 118; and performing a planarization into the dielectric layer to uncover the plurality of sacrificial lines 1802l and the plurality of fin-shaped structures 118. In alternative embodiments, the plurality of isolation walls 102 are formed by some other suitable process.

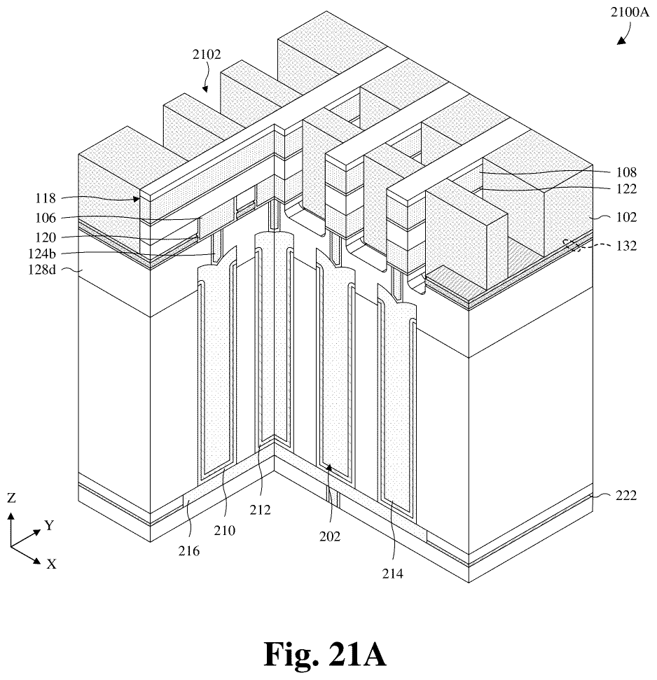

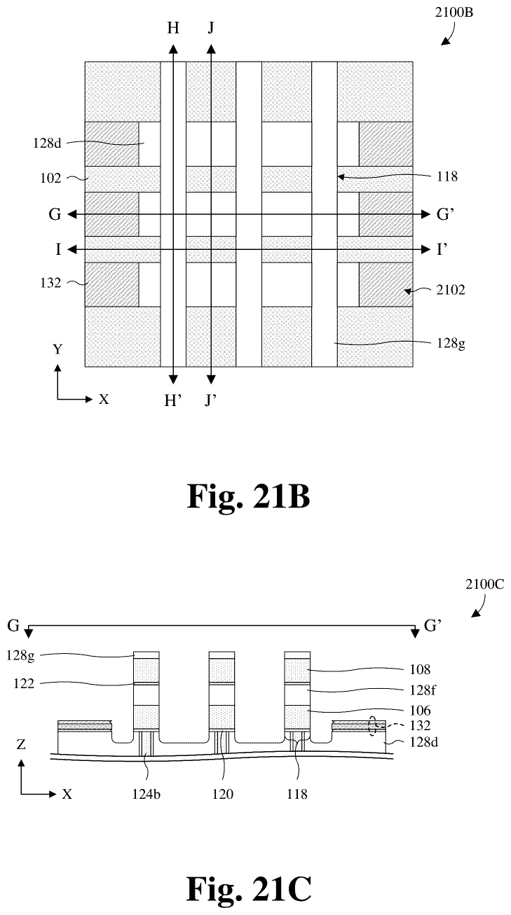

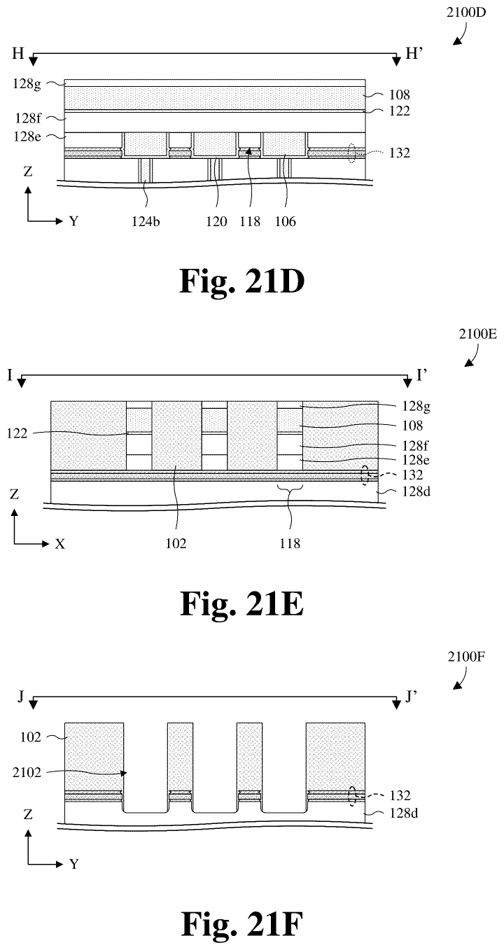

Focusing on views 2100A-2100F of FIGS. 21A-21F, the plurality of sacrificial lines 1802l are removed, thereby leaving a plurality of gaps 2102 between the plurality of fin-shaped structures 118 and the plurality of isolation walls 102. The removal may, for example, be performed by a blanket etch having high selectivity for the plurality of sacrificial lines 1802l relative to other structure surrounding the plurality of sacrificial lines 1802l. In alternative embodiments, the removal may be performed by some other suitable process.

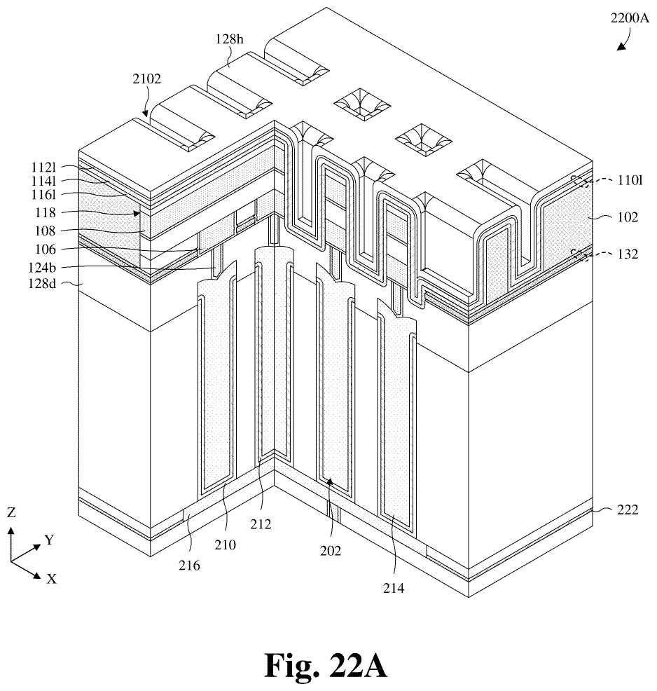

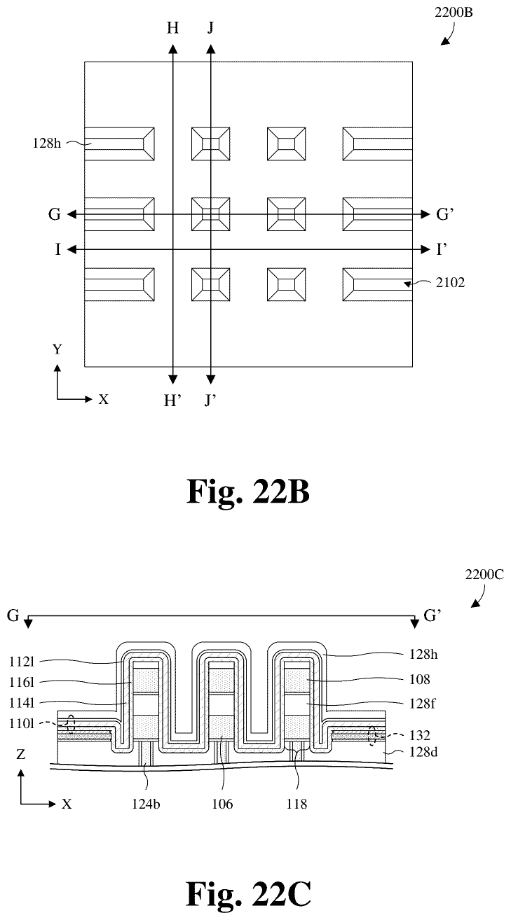

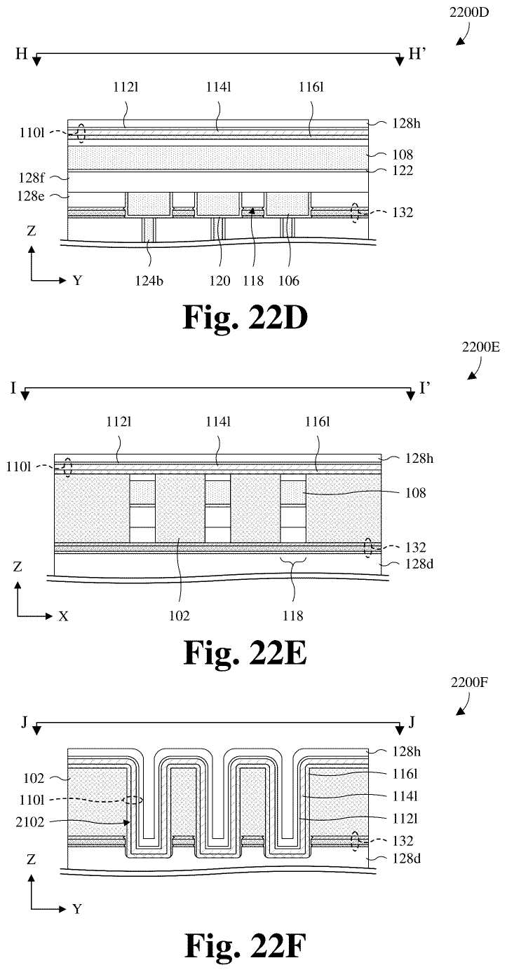

Focusing on views 2200A-2200F of FIGS. 22A-22F, a multi-layer film 110l is deposited overlying the plurality of fin-shaped structures 118 and the plurality of isolation walls 102 and further extending into and conformally lining the plurality of gaps 2102. The multi-layer film 110l comprises a semiconductor layer 116l, a dielectric layer 114l overlying the semiconductor layer 116l, and a conductive layer 112l overlying the dielectric layer 114l. Further, ILD layer 128h is deposited overlying and conformally lining the multi-layer film 110l.

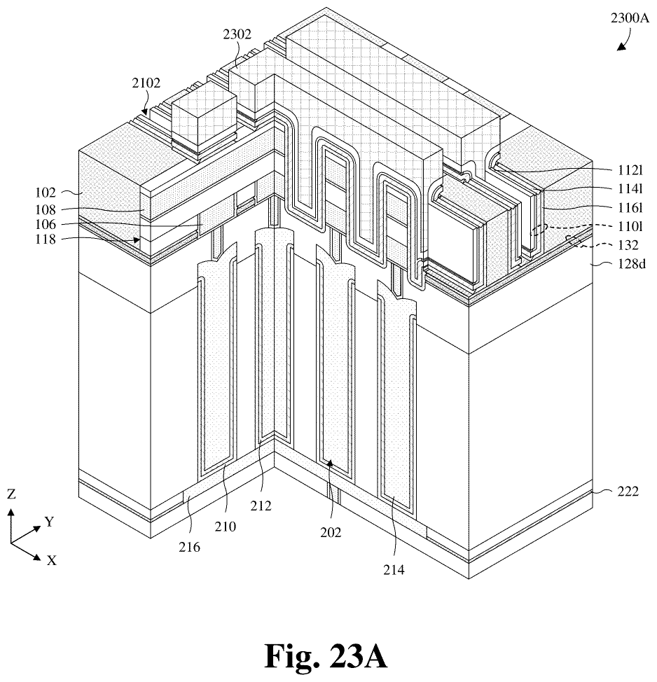

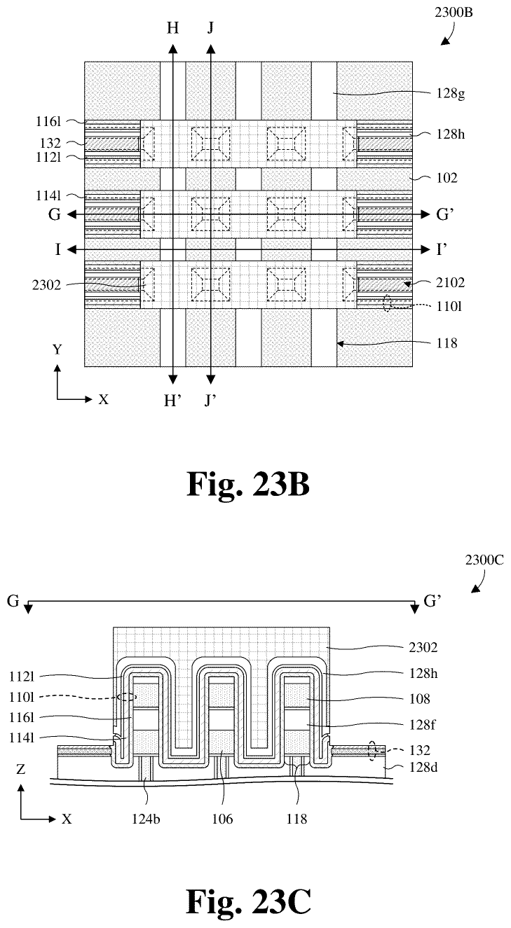

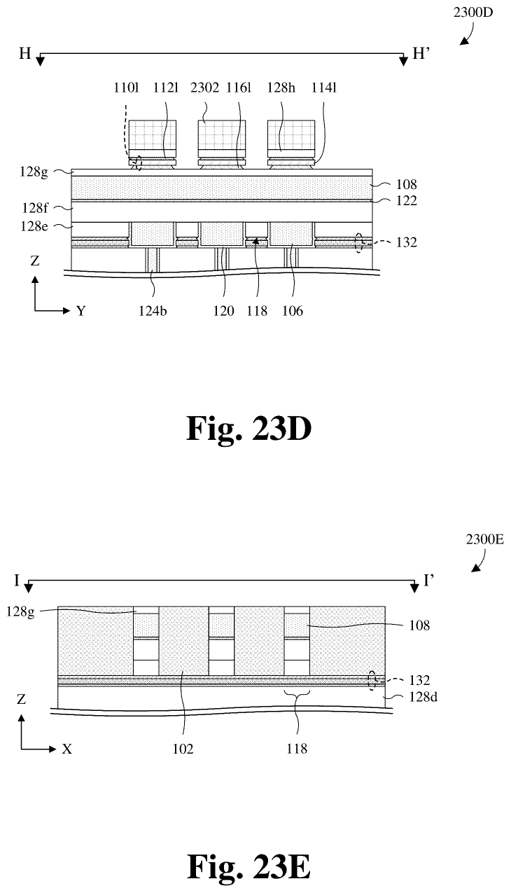

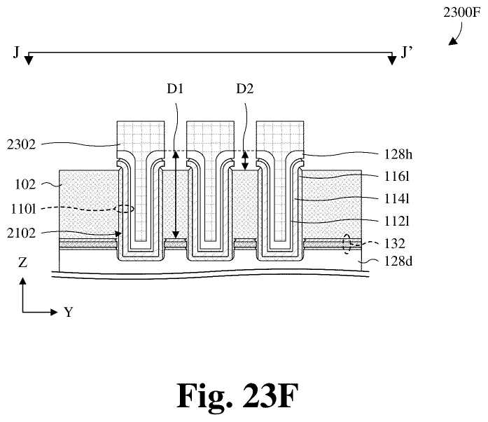

Focusing on views 2300A-2300F of FIGS. 23A-23F, the multi-layer film 110l is cut outside the array of vertical TFTs being formed. Further, the multi-layer film 110l is cut along cut lines elongated in the X direction at boundary regions between rows of the array. Such cutting divides the multi-layer film 110l into a plurality of line-shaped segments that are spaced from each other in the Y direction and elongated in the X direction.

A process for performing the cutting may, for example, comprise: forming a plurality of line-shaped masks 2302 individual to and respectively overlying the rows of vertical TFTs being formed; performing an etch into the multi-layer film 110l with the plurality of line-shaped masks 2302 in place; and removing the plurality of line-shaped masks 2302. The plurality of line-shaped masks 2302 may, for example, be formed by or using photolithography or some other suitable process and/or may, for example, be or comprise a photoresist mask, a hard mask, some other suitable mask, or any combination of the foregoing. In alternative embodiments, the cutting is performed by some other suitable process.

Because the plurality of isolation walls 102 cover sidewalls of the fin-shaped structures 118 outside the array of vertical TFTs being formed and at boundary regions between rows of the array, portions of the multi-layer film 110l that would otherwise deposit on the sidewalls instead deposit on top surfaces of the plurality of isolation walls 102. Hence, these portions are horizontally extending instead of vertically extending. This significantly reduces the amount of vertical etching needed to fully cut the multi-layer film 110l outside the array and at the boundary regions, which alleviates challenges associated with cutting the multi-layer film 110l.

For example, focusing on FIG. 23F, fully etching a vertically extending portion of the multi-layer film 110l would depend on vertical etching to a depth D1. However, this would be time consuming and likely cut into and damage the plurality of drain electrodes 108. Further, only vertically etching to a depth D2 (e.g., equal to a thickness of the multi-layer film 110l or some other suitable value), would fail to fully cut the vertically extending portion and would lead to leakage current between gate electrodes. In contrast, a horizontally extending portion of the multi-layer film 110l may be fully cut by vertical etching to the depth D2, which would not damage the plurality of drain electrodes 108.

In view of the foregoing, the plurality of isolation walls 102 allow the multi-layer film 110l to be readily cut outside the array of vertical TFTs being formed and at boundary regions between rows of the array without having to choose between damaging the plurality of drain electrodes 108 and leakage current between gate electrodes. This, in turn, improves manufacturing yields and reduces manufacturing costs. Further, fully cutting the multi-layer film 110l has the added benefit of reducing parasitic capacitance, which may enhance the switching speed of the vertical TFTs being formed. For example, fully cutting the multi-layer film 110l may reduce the areas of parasitic capacitance formed in part by dielectric and/or conductive material of the multi-layer film 110l.

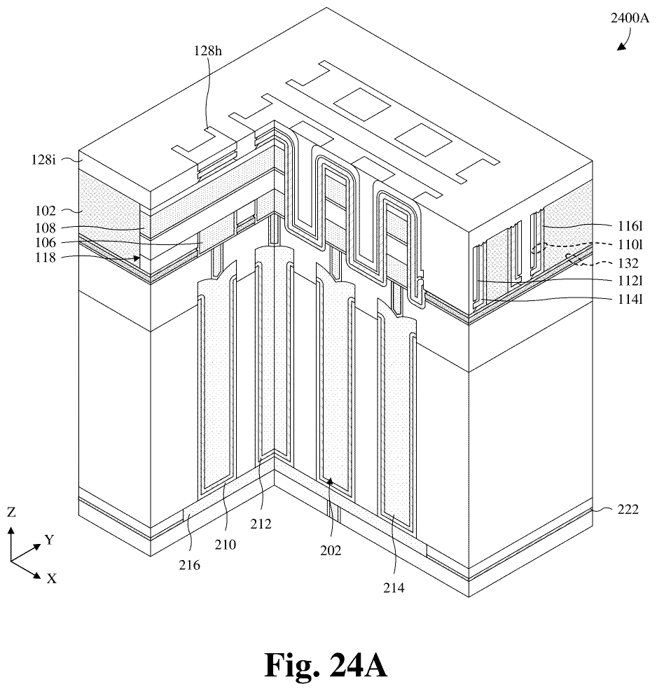

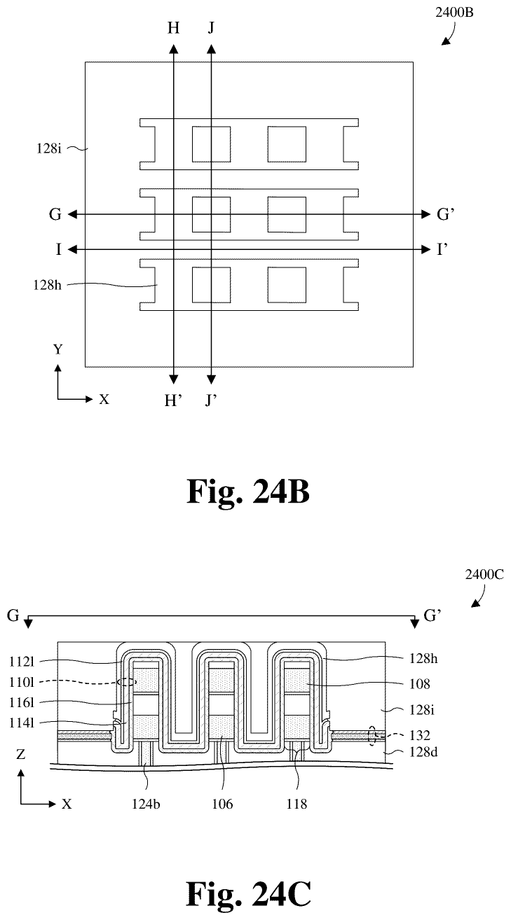

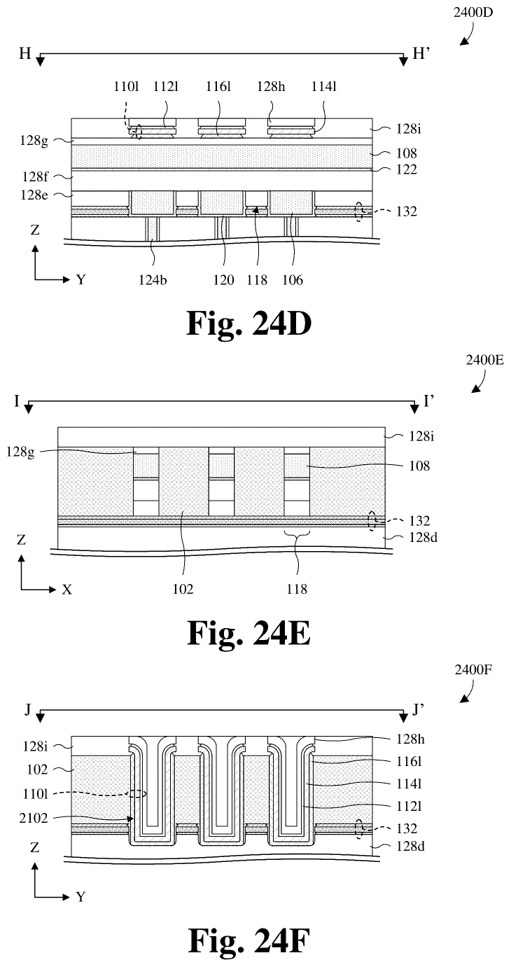

Focusing on views 2400A-2400F of FIGS. 24A-24F, ILD layer 128i is formed filling the plurality of gaps 2102 and surrounding the multi-layer film 110l over the plurality of isolation walls 102 and the plurality of fin-shaped structures 118. A process for forming ILD layer 128i may, for example, comprise depositing ILD layer 128i covering the structure of FIGS. 23A-23F and subsequently performing a planarization into ILD layer 128i to level a top surface of ILD layer 128i with a top surface of the multi-layer film 110l. In alternative embodiments, ILD layer 128i may be formed by some other suitable process. Further, as seen hereafter, ILD layer 128i may not be formed in alternative embodiments.

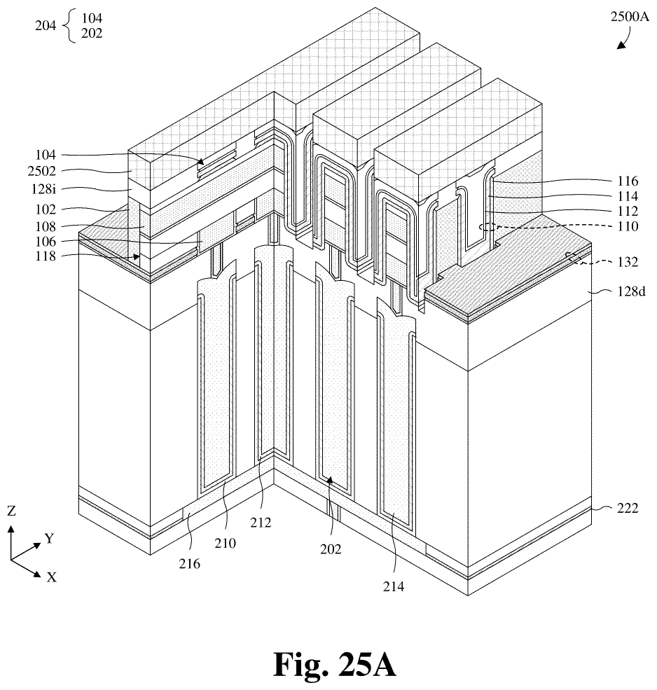

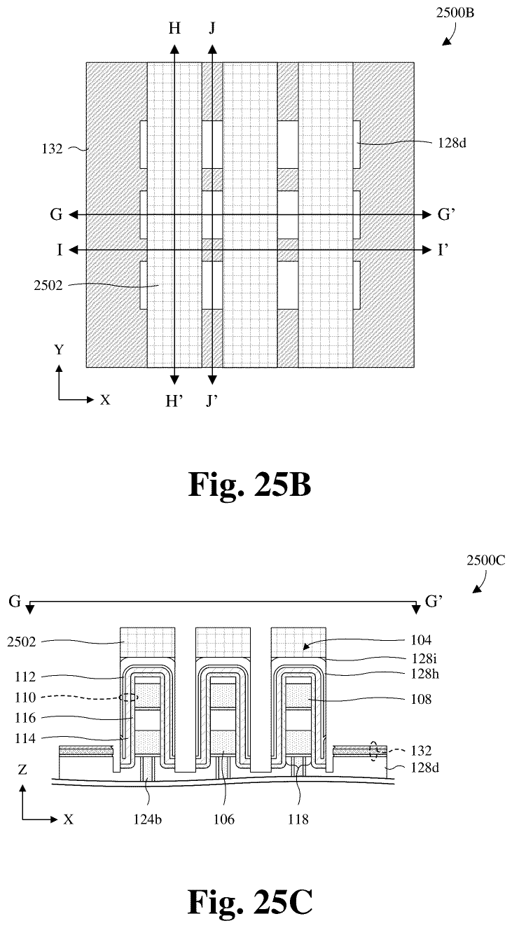

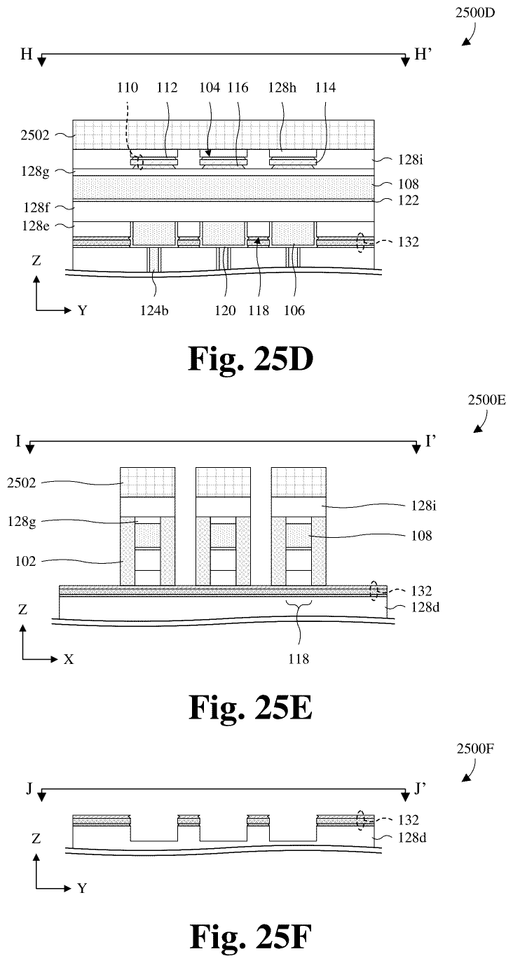

Focusing on views 2500A-2500F of FIGS. 25A-25F, the multi-layer film 110l and the plurality of isolation walls 102 are cut outside the array of vertical TFTs being formed. Further, the multi-layer film 110l and the plurality of isolation walls 102 are cut along cut lines elongated in the Y direction at boundary regions between columns of the array. The cutting divides the multi-layer film 110l into a plurality of film stacks 110. The plurality of film stacks 110 comprise individual gate electrodes 112, individual gate dielectric layers 114, and individual semiconductor channels 116 respectively formed from the conductive layer 112l, the dielectric layer 114l, and the semiconductor layer 116l.

The cutting further completes formation of a plurality of vertical TFTs 104, which are in a plurality of rows and a plurality of columns. Each of the plurality of vertical TFTs 104 comprises an individual source electrode and an individual film stack. Further, for each column, the vertical TFTs in that column share a drain electrode. The plurality of vertical TFTs 104 are paired with and electrically coupled respectively to the plurality of storage structures 202 to form a plurality of 1T-1SN memory structures 204.

A process for performing the cutting may, for example, comprise: forming a plurality of line-shaped masks 2502 individual to and respectively overlying the columns of vertical TFTs being formed; performing an etch into the multi-layer film 110l and the plurality of isolation walls 102 with the plurality of line-shaped masks 2502 in place; and removing the plurality of line-shaped masks 2502. The plurality of line-shaped masks 2502 may, for example, be formed by or using photolithography or some other suitable process and/or may, for example, be or comprise a photoresist mask, a hard mask, some other suitable mask, or any combination of the foregoing. In alternative embodiments, the cutting is performed by some other suitable process.

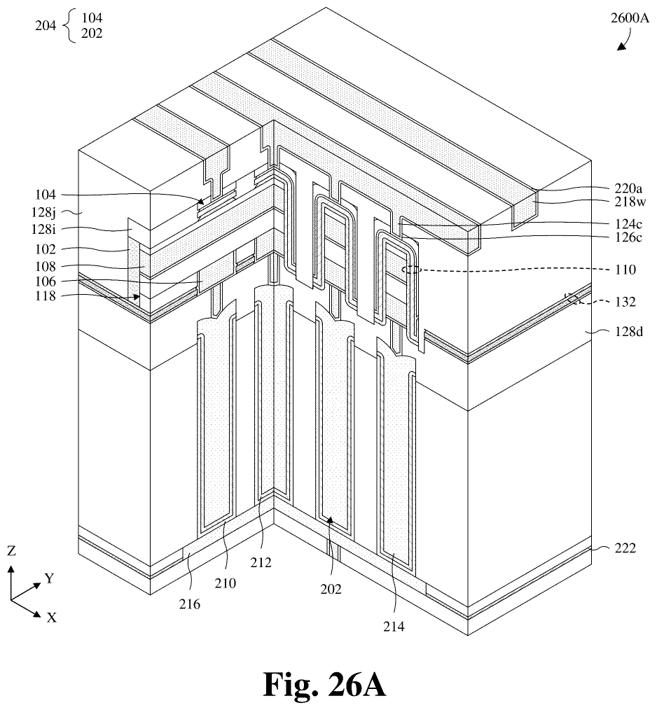

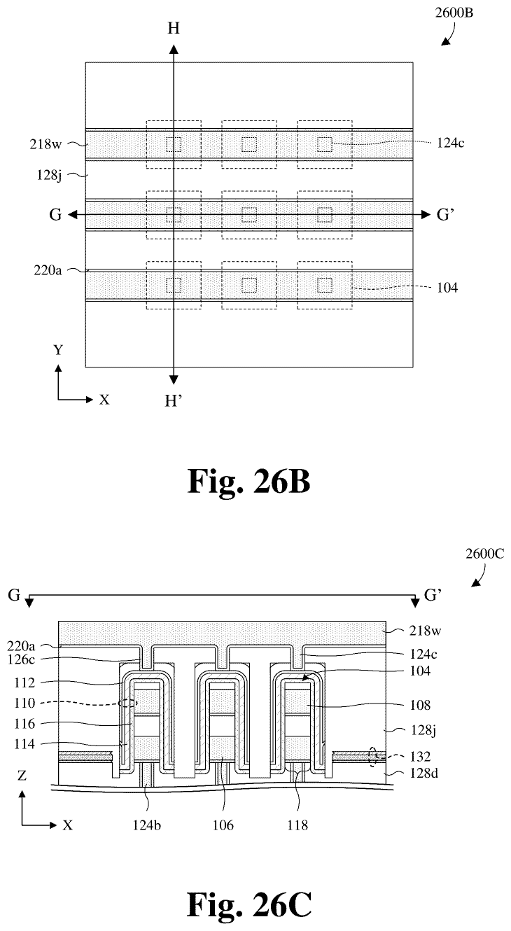

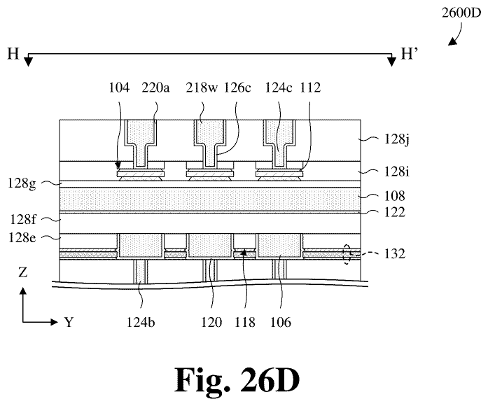

Focusing on views 2600A-2600D of FIGS. 26A-26D, ILD layer 128j is formed covering the plurality of vertical TFTs 104 with a flat top surface. A process for forming ILD layer 128j may, for example, comprise depositing ILD layer 128j covering the plurality of vertical TFTs 104 and subsequently performing a planarization into ILD layer 128j. Alternatively, ILD layer 128i may be formed by some other suitable process.

Additionally, a plurality of word lines 218w and vias 124c are formed inset into ILD layer 128j. The plurality of word lines 218w are individual to and respectively overlie the rows of vertical TFTs, and vias 124c extend respectively from the plurality of word lines 218w respectively to the gate electrodes 112 of the vertical TFTs 104.

The plurality of word lines 218w comprise individual wire bodies and individual wire liners 220a, whereas the plurality of vias 124c comprise individual via bodies and individual via liners 126c. Note that for ease of illustration, the via bodies and the wire bodies are labeled respectively as vias 124c and the plurality of word lines 218w. Further, the via bodies and the wire bodies correspond to different portions of conductive body layers spanning a wire level and a via level. Similarly, via liners 126c and wire liners 220a correspond to different portions of conductive liner layers spanning the wire and via levels.

A process for forming the plurality of word lines 218w and vias 124c may, for example, comprise: patterning ILD layer 128j and ILD layer 128h to form wire openings and via openings overlapping with the wire openings; depositing a conductive liner layer lining the openings; depositing a conductive body layer filling the openings over the conductive liner layer; and performing a planarization into the conductive liner layer and the conductive body layer to expose a top surface of ILD layer 128j. The patterning may, for example, be or comprise a photolithography/etching process or some other suitable patterning process. In alternative embodiments, the plurality of word lines 218w and vias 124c are formed by some other suitable process.

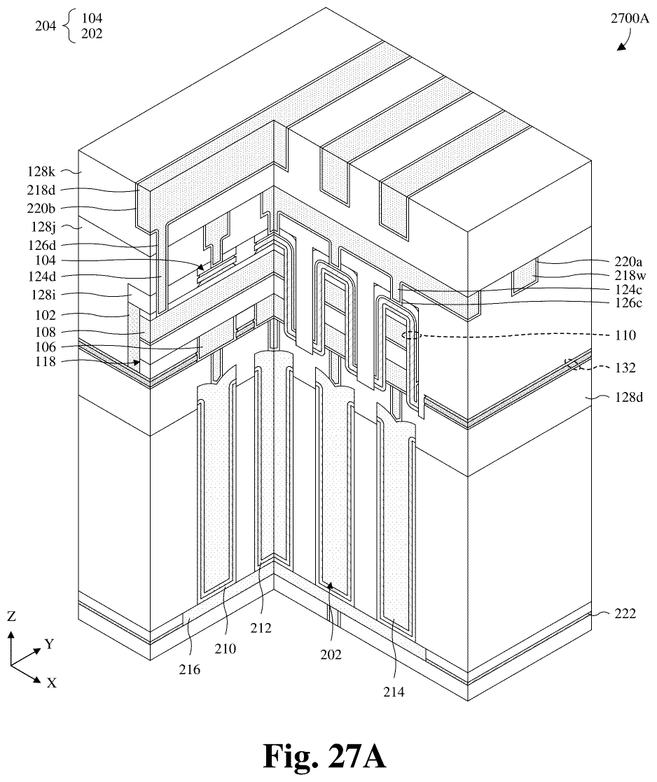

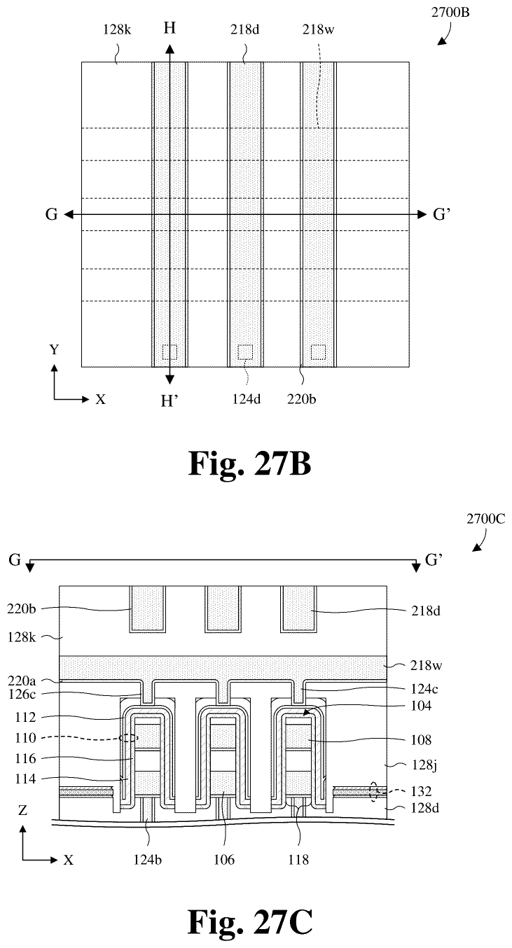

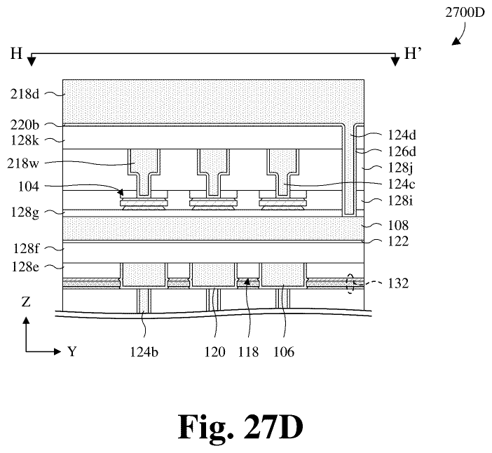

Focusing on views 2700A-2700D of FIGS. 27A-27D, ILD layer 128k is formed covering the plurality of word lines 218w with a flat top surface. A process for forming ILD layer 128k may, for example, comprise depositing ILD layer 128k covering the plurality of word lines 218w and subsequently performing a planarization into ILD layer 128k. Alternatively, ILD layer 128k may be formed by some other suitable process.

Additionally, a plurality of drain wires 218d and vias 124d are formed inset into ILD layer 128k. The plurality of drain wires 218d are individual to and respectively overlie the columns of vertical TFTs, and vias 124d extend respectively from the plurality of drain wires 218d respectively to the plurality of drain electrodes 108.

The plurality of drain wires 218d comprise individual wire bodies and individual wire liners 220b, whereas vias 124d comprise individual via bodies and individual via liners 126d. Note that for ease of illustration, the via bodies and the wire bodies are labeled respectively as vias 124d and the plurality of drain wires 218d. Further, the via bodies and the wire bodies correspond to different portions of conductive body layers spanning a wire level and a via level. Similarly, via liners 126d and wire liners 220b correspond to different portions of conductive liner layers spanning the wire and via levels.

A process for forming the plurality of drain wires 218d and vias 124d may, for example, comprise: patterning various ILD layers (e.g., ILD layer 128k and ILD layer 128i) to form wire openings and via openings overlapping with the wire openings; depositing a conductive liner layer lining the openings; depositing a conductive body layer filling the openings over the conductive liner layer; and performing a planarization into the conductive liner layer and the conductive body layer to expose a top surface of ILD layer 128k. The patterning may, for example, be or comprise a photolithography/etching process or some other suitable patterning process. In alternative embodiments, the plurality of drain wires 218d and vias 124d are formed by some other suitable process.

While FIGS. 9A-9D to FIGS. 27A-27D are described with reference to a method, it will be appreciated that the structures shown in these figures are not limited to the method but rather may stand alone separate from the method. While FIGS. 9A-9D to FIGS. 27A-27D are described as a series of acts, it will be appreciated that the order of the acts may be altered in other embodiments. While FIGS. 9A-9D to FIGS. 27A-27D illustrate and describe as a specific set of acts, some acts that are illustrated and/or described may be omitted in other embodiments. Further, acts that are not illustrated and/or described may be included in other embodiments.

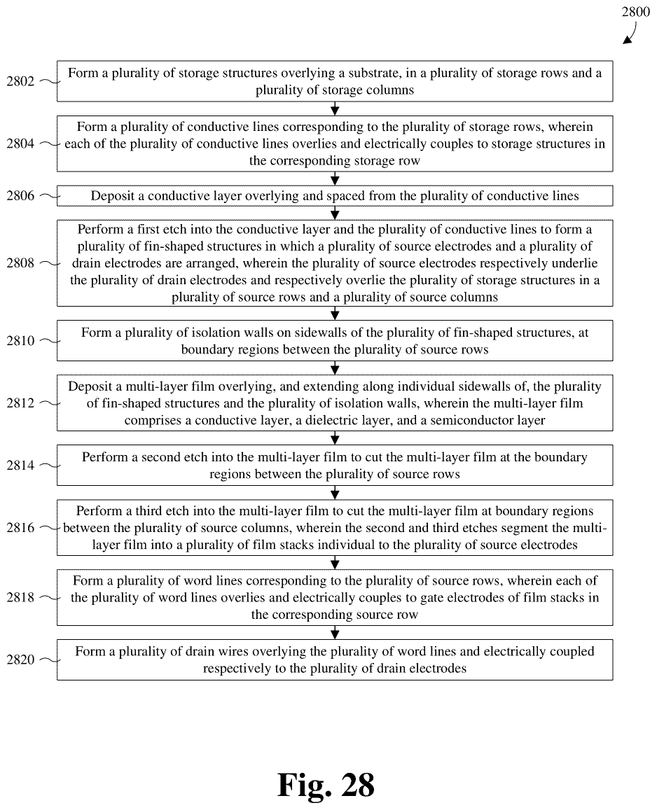

With reference to FIG. 28, a block diagram 2800 of some embodiments of the method of FIGS. 9A-9D to FIGS. 27A-27D is provided.

At act 2802, a plurality of storage structures are formed overlying a substrate, in a plurality of storage rows and a plurality of storage columns. See, for example, FIGS. 9A-9D to FIGS. 11A-11D.

At act 2804, a plurality of conductive lines corresponding to the plurality of storage rows are formed, wherein each of the plurality of conductive lines overlies and electrically couples to storage structures in the corresponding storage row. See, for example, FIGS. 12A-12D to FIGS. 15A-15D.

At act 2806, a conductive layer is deposited overlying and spaced from the plurality of conductive lines. See, for example, FIGS. 16A-16D.

At act 2808, a first etch is performed into the conductive layer and the plurality of conductive lines to form a plurality of fin-shaped structures in which a plurality of source electrodes and a plurality of drain electrodes are arranged, wherein the plurality of source electrodes respectively underlie the plurality of drain electrodes and respectively overlie the plurality of storage structures in a plurality of source rows and a plurality of source columns. See, for example, FIGS. 17A-17F.

At act 2810, a plurality of isolation walls are formed on sidewalls of the plurality of fin-shaped structures, at boundary regions between the plurality of source rows. See, for example, FIGS. 18A-18F to FIGS. 21A-21F.

At act 2812, a multi-layer film is deposited overlying, and extending along individual sidewalls of, the plurality of fin-shaped structures and the plurality of isolation walls, wherein the multi-layer film comprises a conductive layer, a dielectric layer, and a semiconductor layer. See, for example, FIGS. 22A-22F.

At act 2814, a second etch is performed into the multi-layer film to cut the multi-layer film at the boundary regions between the plurality of source rows. See, for example, FIGS. 23A-23F.

At act 2816, a third etch is performed into the multi-layer film to cut the multi-layer film at boundary regions between the plurality of source columns, wherein the second and third etches segment the multi-layer film into a plurality of film stacks individual to a plurality of source electrodes. See, for example, FIGS. 24A-24F to FIGS. 25A-25F.

At act 2818, a plurality of word lines corresponding to the plurality of source rows are formed, wherein each of the plurality of word lines overlies and electrically couples to gate electrodes of film stacks in the corresponding source row. See, for example, FIGS. 26A-26F.

At act 2820, a plurality of drain wires are formed overlying the plurality of word lines and electrically coupled respectively to the plurality of drain electrodes. See, for example, FIGS. 27A-27F.

While the block diagram 2800 of FIG. 28 is illustrated and described herein as a series of acts or events, it will be appreciated that the illustrated ordering of such acts or events is not to be interpreted in a limiting sense. For example, some acts may occur in different orders and/or concurrently with other acts or events apart from those illustrated and/or described herein. Further, not all illustrated acts may be required to implement one or more aspects or embodiments of the description herein, and one or more of the acts depicted herein may be carried out in one or more separate acts and/or phases.

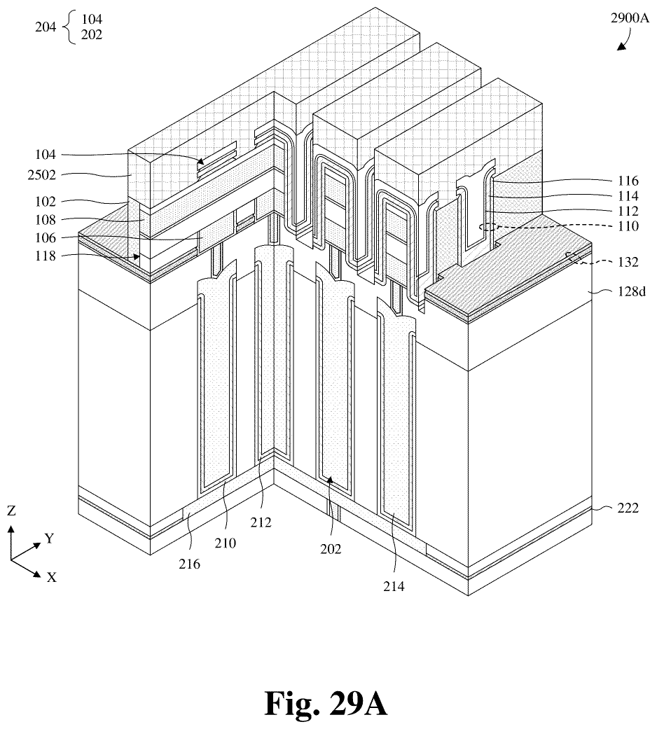

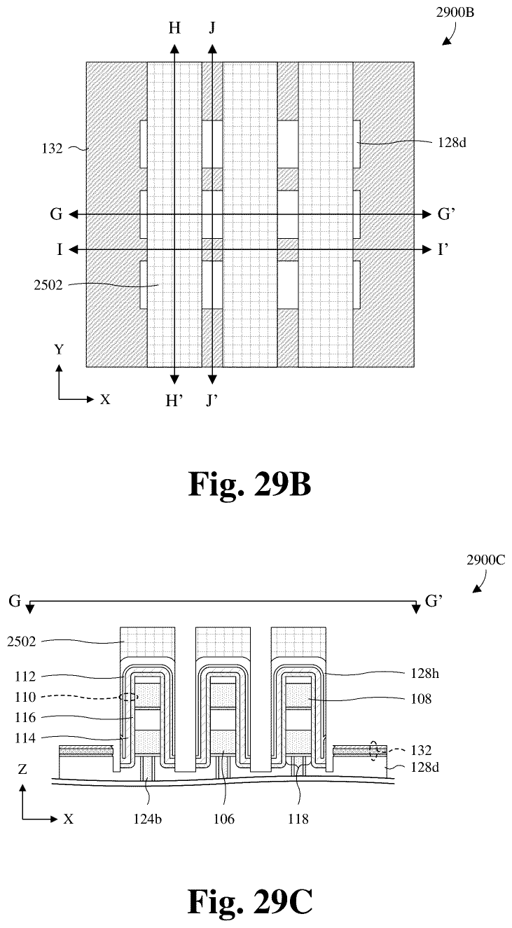

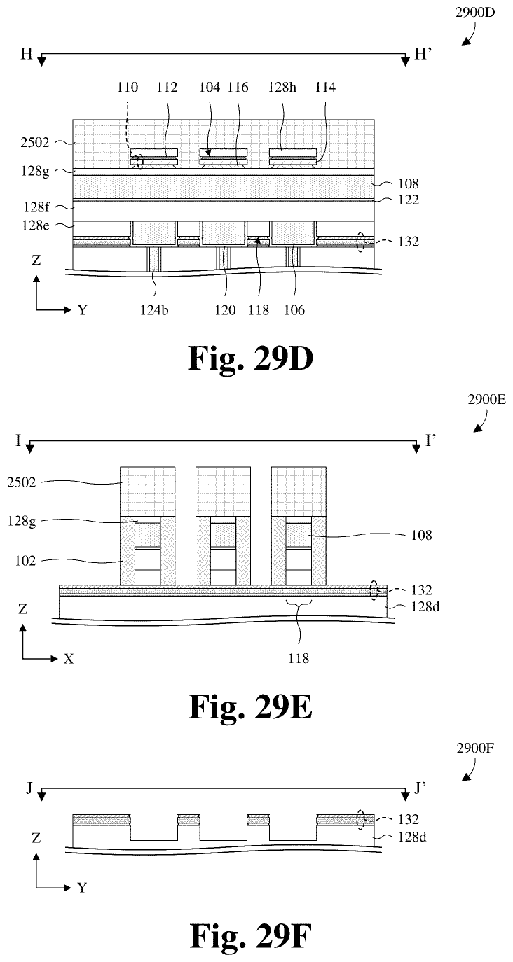

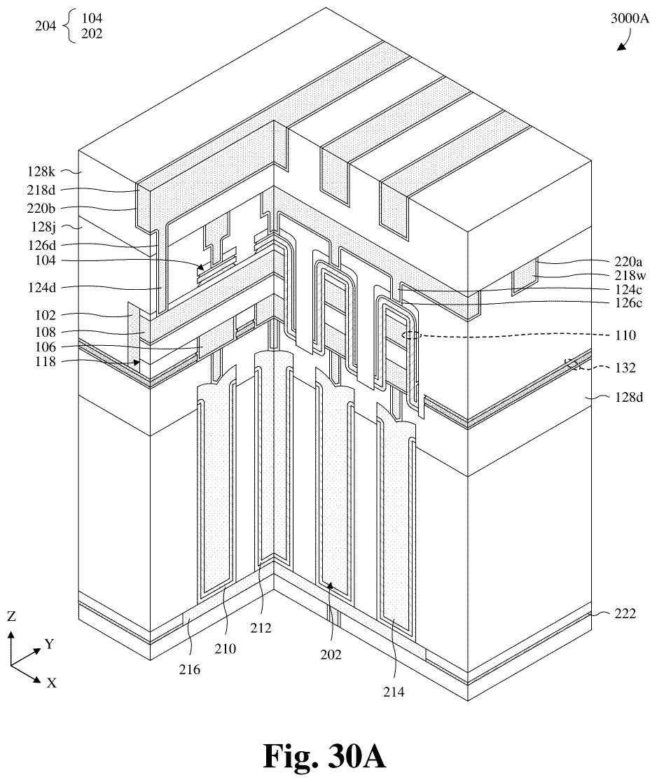

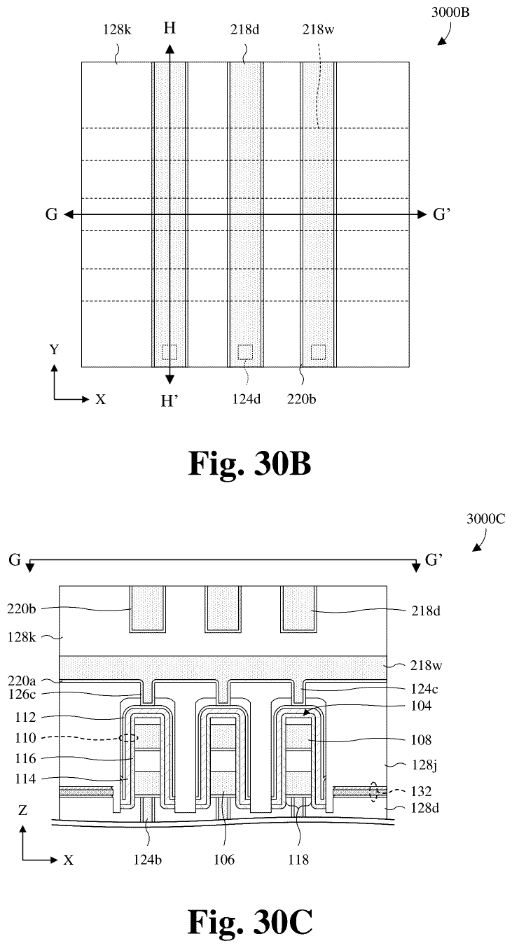

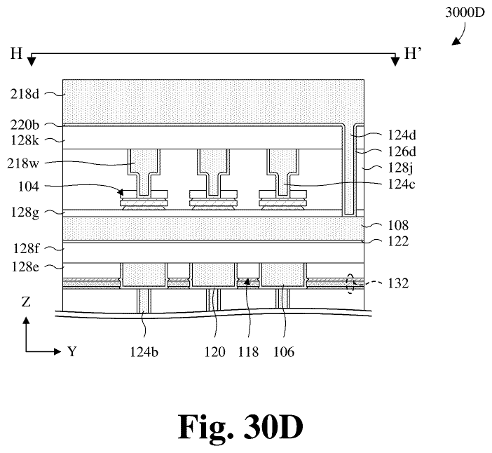

With reference to FIGS. 29A-29F and FIGS. 30A-30D, a series of views of some alternative embodiments of the method of FIGS. 9A-9D to FIGS. 27A-27D is provided in which no ILD layer is formed between the cutting at FIGS. 23A-23F and the cutting at FIGS. 25A-25F.

Focusing on views 2900A-2900F of FIGS. 29A-29F, the acts described with regard to FIGS. 9A-9D to FIGS. 25A-25F are performed as described above, except the acts described with regard to FIGS. 24A-24F are skipped. In other words, ILD layer 128i is not formed between the cutting at FIGS. 23A-23F and the cutting at FIGS. 25A-25F. Because the planarization used during formation of ILD layer 128i may, for example, be difficult to control and perform uniformly, skipping formation of ILD layer 128i may increase uniformity amongst the plurality of vertical TFTs 104 and may hence improve manufacturing yields.

Focusing on views 3000A-3000D of FIGS. 30A-30D, the acts described with regard to FIGS. 26A-26D to FIGS. 27A-27D are performed as described above to form the plurality of word lines 218w and the plurality of drain wires 218d.

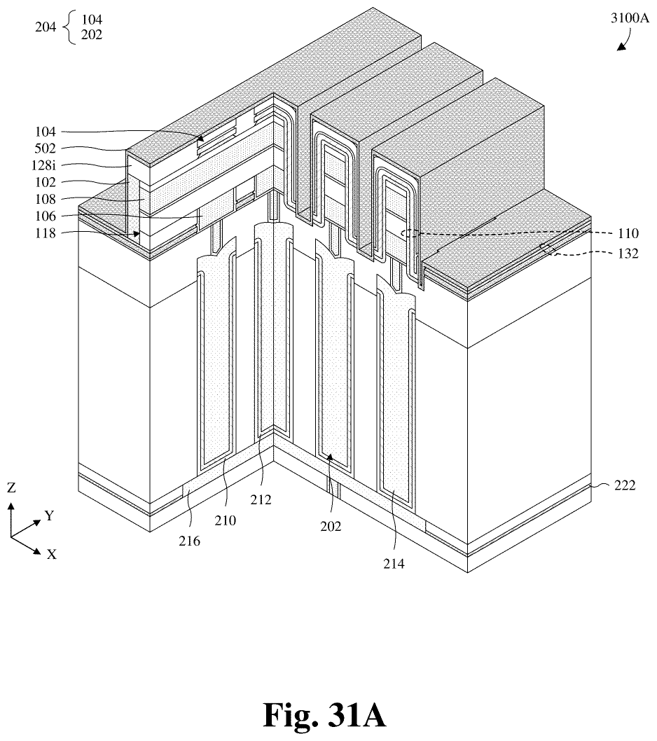

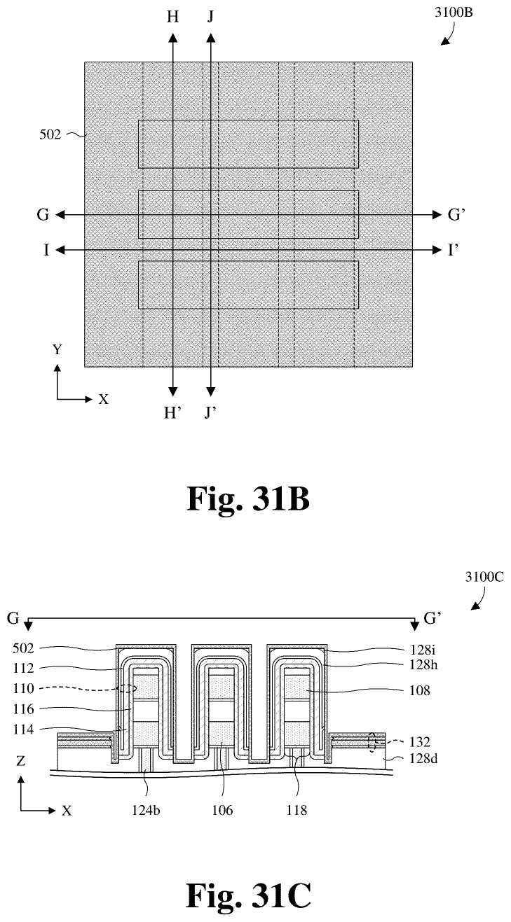

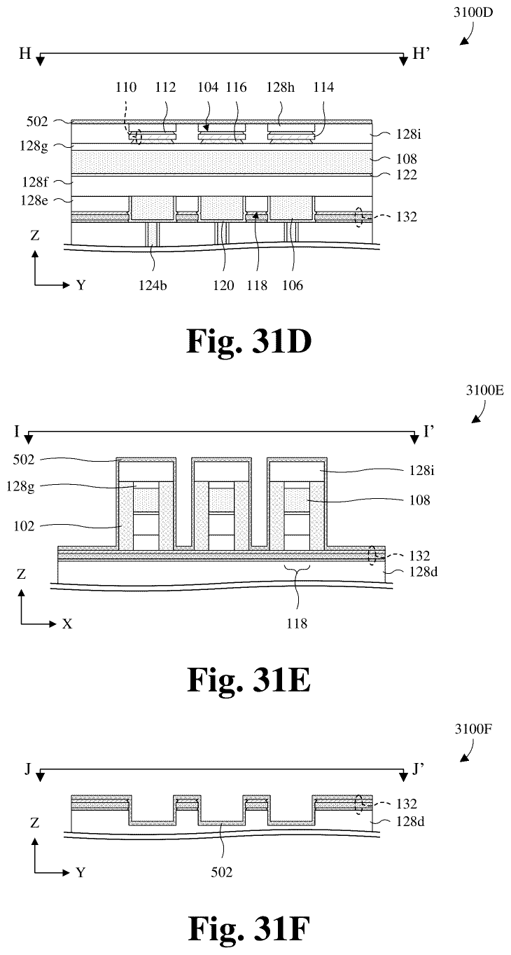

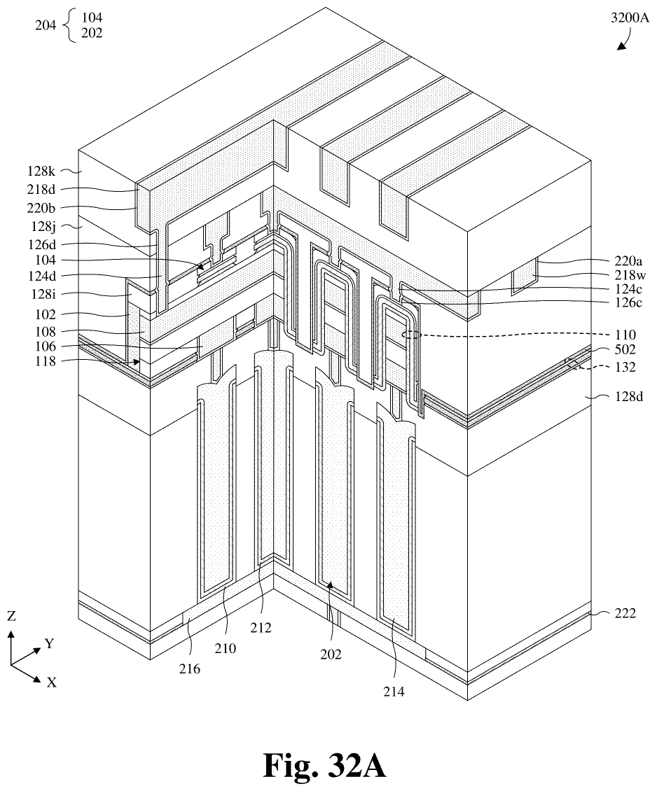

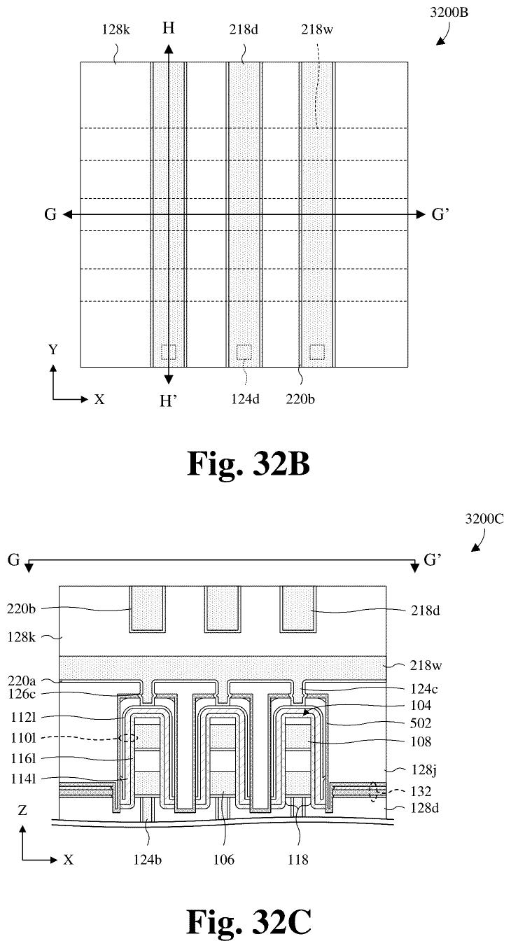

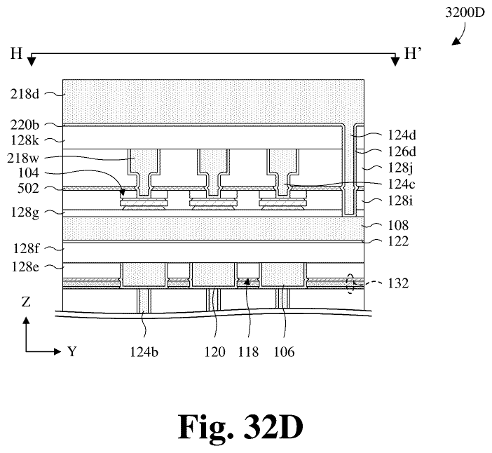

With reference to FIGS. 31A-31F to FIGS. 32A-32D, a series of views of some alternative embodiments of the method of FIGS. 9A-9D to FIGS. 27A-27D is provided in which a channel protection layer 502 is formed. The method may, for example, be employed to form the semiconductor structure of FIG. 6 or some other suitable semiconductor structure.

Focusing on views 3100A-3100F of FIGS. 31A-31F, the acts described with regard to FIGS. 9A-9D to FIGS. 25A-25F are performed as described above. Thereafter, a channel protection layer 502 is deposited overlying and extending along sidewalls of the plurality of vertical TFTs 104 so as to surround the plurality of vertical TFTs 104.

The channel protection layer 502 is configured to block hydrogen, oxygen, and other errant particles from reaching the plurality of vertical TFTs 104. Such errant particles may, for example, enter the semiconductor structure during subsequent manufacturing processes. The channel protection layer 502 may, for example, be or comprise aluminum oxide (e.g., AlO), silicon oxycarbide (SiOC), chromium oxide (e.g., Cr₂O₃), hafnium oxide (e.g., HfO), other suitable materials, or any combination of the foregoing.

By blocking errant particles from reaching the plurality of vertical TFTs 104, the channel protection layer 502 may, for example, improve device reliability and improve manufacturing yields. For example, hydrogen that diffuses to the semiconductor channels 116 may shift threshold voltages of the plurality of vertical TFTs 104 in uncontrolled ways that degrade reliability of the plurality of vertical TFTs 104.

Focusing on views 3200A-3200D of FIGS. 30A-30D, the acts described with regard to FIGS. 26A-26D to FIGS. 27A-27D are performed as described above to form the plurality of word lines 218w and the plurality of drain wires 218d.

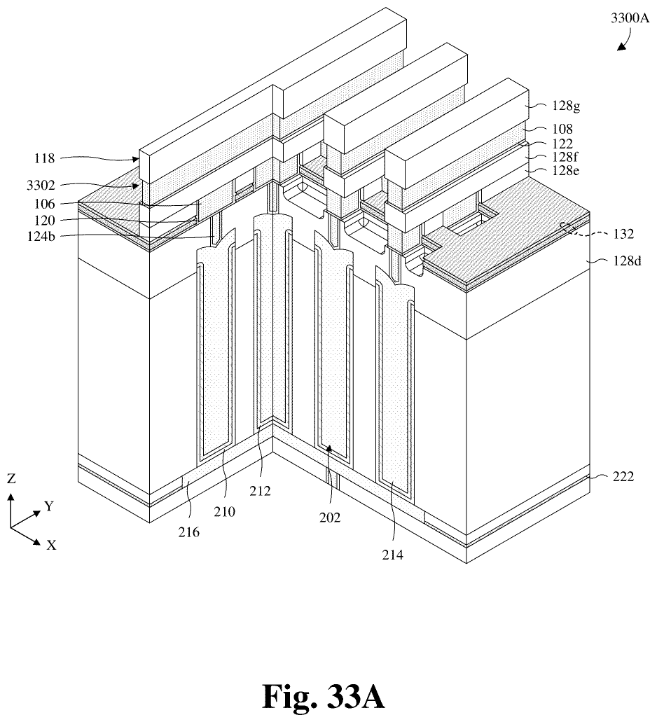

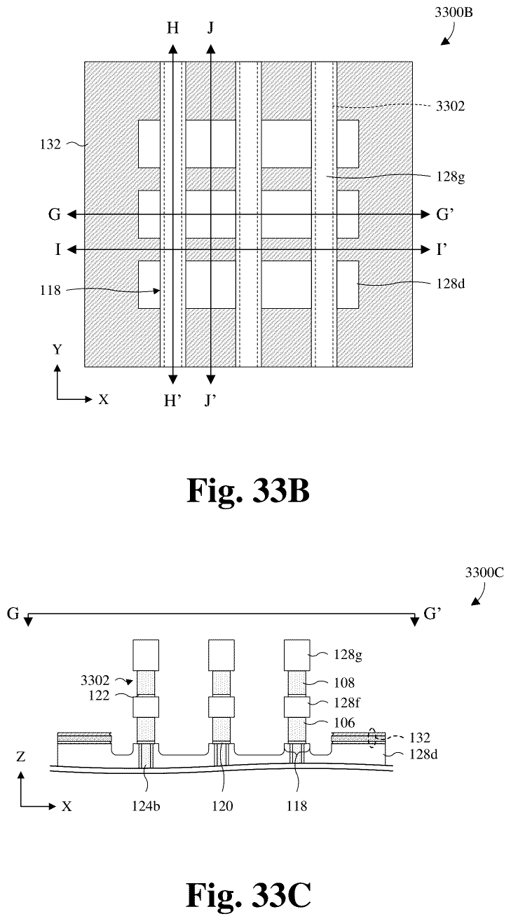

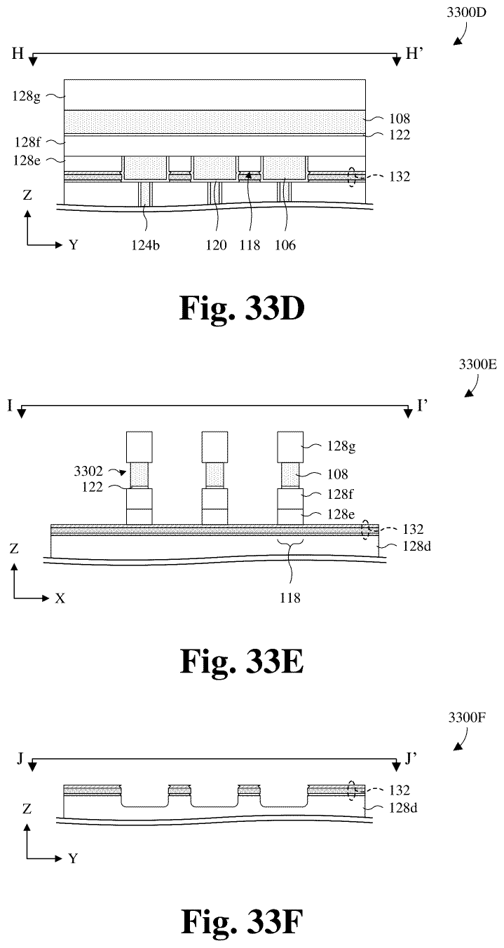

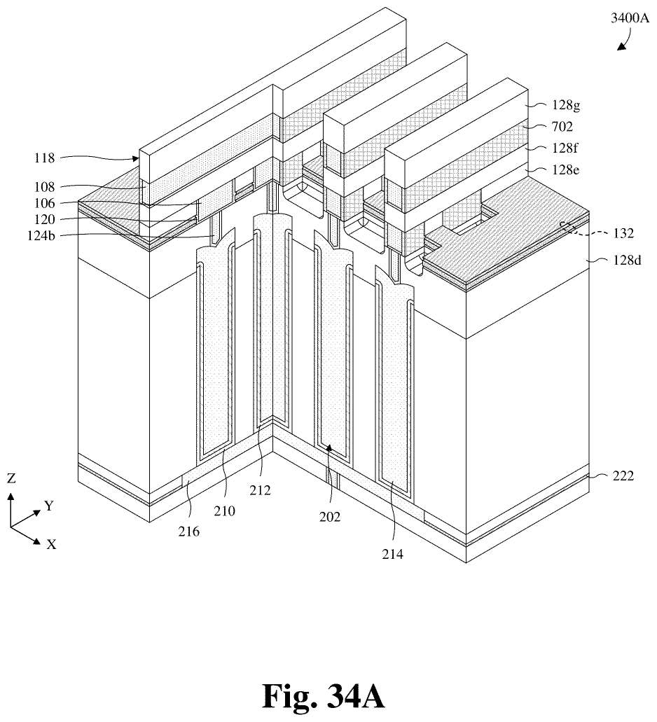

With reference to FIGS. 33A-33F to FIGS. 35A-35D, a series of views of some alternative embodiments of the method of FIGS. 9A-9D to FIGS. 27A-27D is provided in which a channel protection layer 502 and a plurality of source/drain liners 702 are formed. The method may, for example, be employed to form the semiconductor structure of FIG. 8A or some other suitable semiconductor structure.

Focusing on views 3300A-3300F of FIGS. 33A-33F, the acts described with regard to FIGS. 9A-9D to FIGS. 17A-17F are performed as described above. Thereafter, the plurality of source electrodes 106 and the plurality of drain electrodes 108 are laterally etched to create a plurality of recesses 3302 in sidewalls of the fin-shaped structures 118. The lateral etching may, for example, be performed with a wet etch having a high selectivity for the plurality of source electrodes 106 and the plurality of drain electrodes 108 relative to surrounding structure. Alternatively, the lateral etching may be performed by some other suitable process.

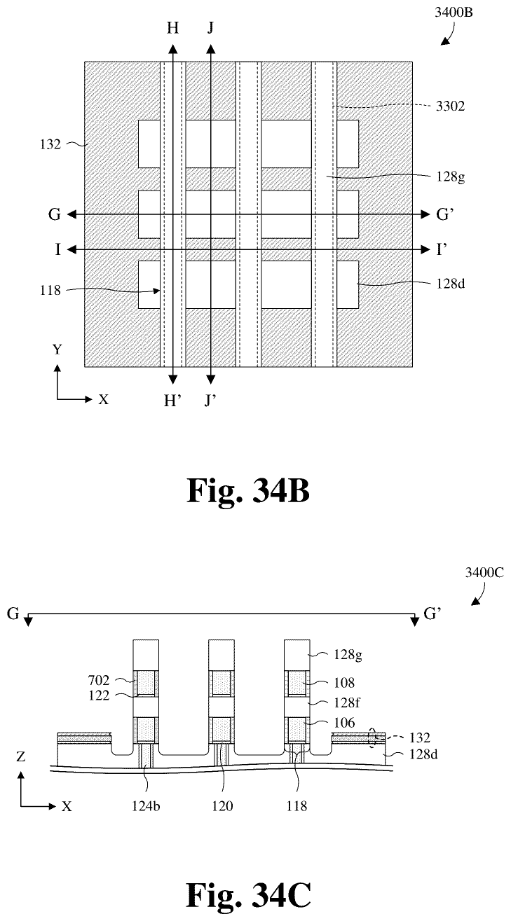

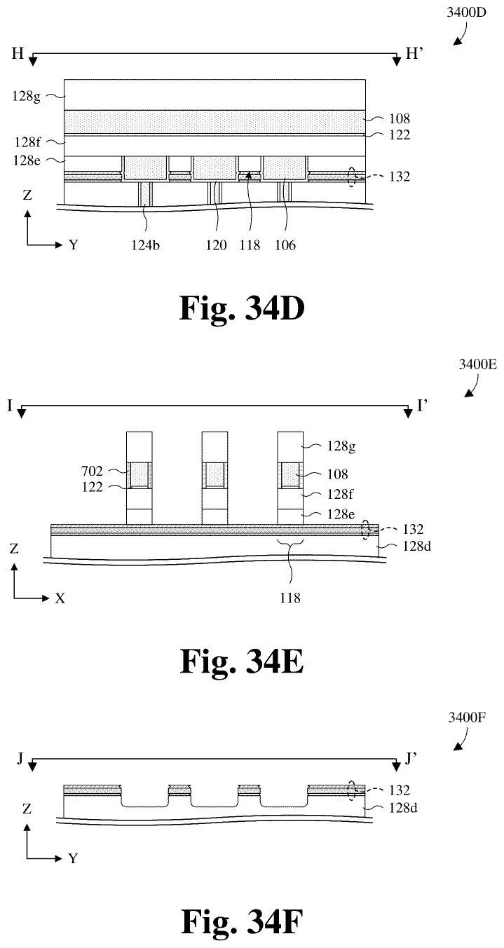

Focusing on views 3400A-3400F of FIGS. 34A-34F, a plurality of source/drain liners 702 are formed respectively filling the plurality of recesses 3302. The plurality of source/drain liners 702 are configured to reduce contact resistance from the plurality of source electrodes 106 and the plurality of drain electrodes 108 respectively to semiconductor channels hereafter formed by creating an ohmic-like contact. The plurality of source/drain liners 702 are a different semiconductor material than the semiconductor channels and may, for example, be or comprise indium gallium zinc oxide (e.g., IGZO), indium oxide (e.g., InO), zinc oxide (e.g., ZnO), indium zinc oxide (e.g., InZnO), indium tungsten oxide (e.g., IWO), tin oxide (e.g., ZnO), some other suitable semiconductor material, or any combination of the foregoing.

In some embodiments, the ohmic-like contact results from the plurality of source/drain liners 702 having a small width that promotes carrier tunneling through the plurality of source/drain liners 702. For example, the plurality of source/drain liners 702 may have widths of 1-10 nanometers, 10-20 nanometers, or some other suitable value.

A process for filling the plurality of recesses 3302 may, for example, comprise: depositing a liner layer overlying and lining the plurality of fin-shaped structures 118 and further filling the plurality of recesses 3302; and etching back the liner layer to clear the liner outside the plurality of recesses 3302. In alternative embodiments, the plurality of source/drain liners 702 may be formed by some other suitable process.

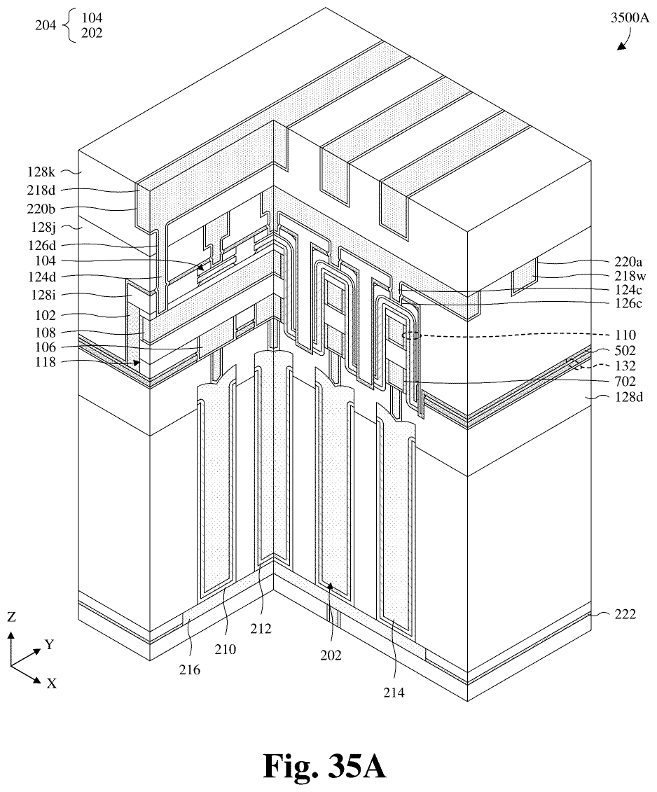

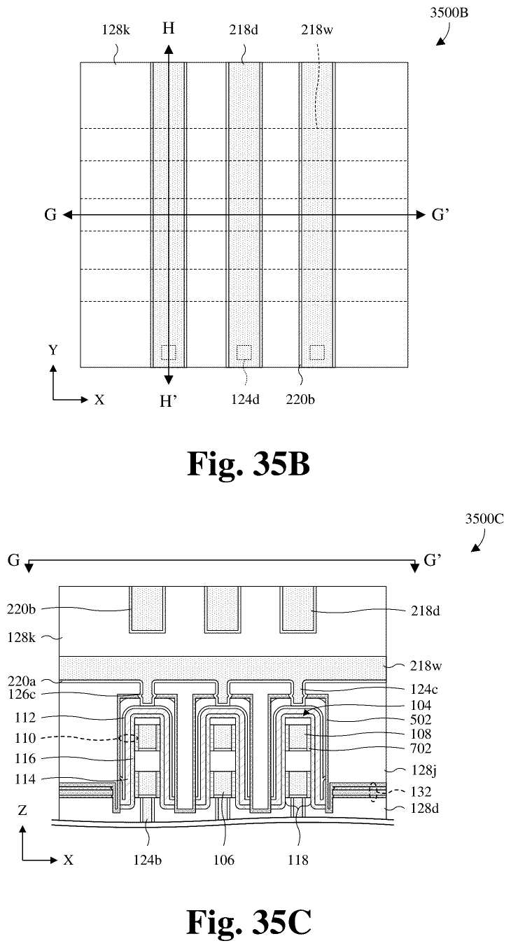

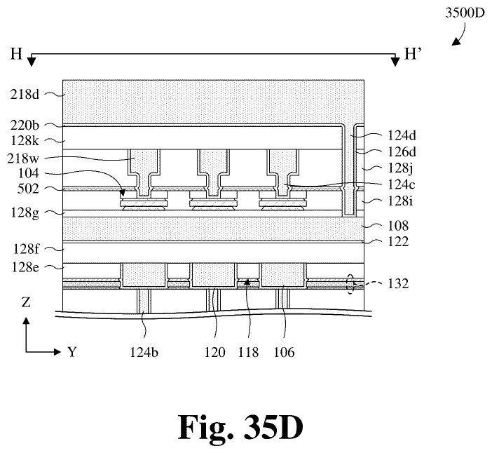

Focusing on views 3500A-3500D of FIGS. 35A-35D, the acts described with regard to FIGS. 18A-18F to FIGS. 27A-27D, as well as formation of the channel protection layer 502 as described with regard to FIGS. 31A-31F, are performed to complete the semiconductor structure. For example, the plurality of isolation walls 102 are formed, the multi-layer film 110l is deposited and cut into the film stacks 110 to complete formation of the vertical TFTs 104, and the plurality of word lines 218w and the plurality of drain wires 218d are formed. In alternative embodiments, formation of the channel protection layer 502 is skipped.

While FIGS. 29A-29F to FIGS. 35A-35D are described with reference to methods, it will be appreciated that the structures shown in these figures are not limited to the method but rather may stand alone separate from the method. While FIGS. 29A-29F to FIGS. 35A-35D are described as a series of acts, it will be appreciated that the order of the acts may be altered in other embodiments. While FIGS. 29A-29F to FIGS. 35A-35D illustrate and describe as a specific set of acts, some acts that are illustrated and/or described may be omitted in other embodiments. Further, acts that are not illustrated and/or described may be included in other embodiments.

Accordingly, in some embodiments, the present disclosure relates to a method, including: forming a fin-shaped structure including a drain electrode and a pair of source electrodes underlying the drain electrode; forming an isolation wall covering a sidewall portion of the fin-shaped structure at a boundary region laterally between the pair of source electrodes; depositing a gate layer overlying the fin-shaped structure and the isolation wall at the boundary region, and extending along a sidewall portion of the fin-shaped structure and a sidewall of the isolation wall outside the boundary region; and performing a first etch into the gate layer to cut the gate layer over the fin-shaped structure and the isolation wall, at the boundary region.

In other embodiments, the present disclosure relates to a method, including: forming multiple conductive lines laterally elongated in a first direction; depositing a conductive layer overlying and spaced from the multiple conductive lines; performing a first etch into the conductive layer and the multiple conductive lines to form multiple fin-shaped structures laterally elongated in a second direction transverse to the first direction and in which multiple source electrodes are in multiple rows and multiple columns; forming multiple isolation walls elongated in the first direction and respectively at boundary regions between the multiple rows; depositing a multi-layer film overlying, and extending along individual sidewalls of, the multiple fin-shaped structures and the multiple isolation walls, wherein the multi-layer film includes a gate layer and a semiconductor channel layer; and segmenting the multi-layer film into multiple film stacks that are spaced from each other and individual to the multiple source electrodes.

In yet other embodiments, the present disclosure relates to a semiconductor structure, including: a first source electrode and a second source electrode over a substrate; a drain electrode overlying and spaced from the first and second source electrodes; a first gate electrode overlying the drain electrode and extending along a sidewall of the drain electrode and a sidewall of the first source electrode that face a first direction; and a second gate electrode overlying the drain electrode and extending along the sidewall of the drain electrode and a sidewall of the second source electrode that face the first direction, wherein the first and second gate electrodes are spaced from each other along the sidewall of the drain electrode.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a fin-shaped structure comprising a drain electrode and a pair of source electrodes underlying the drain electrode;
forming an isolation wall covering a sidewall portion of the fin-shaped structure at a boundary region laterally between the pair of source electrodes;
depositing a gate layer overlying the fin-shaped structure and the isolation wall at the boundary region, and extending along a sidewall portion of the fin-shaped structure and a sidewall of the isolation wall outside the boundary region; and
performing a first etch into the gate layer to cut the gate layer over the fin-shaped structure and the isolation wall, at the boundary region.

2. The method according to claim 1, further comprising:
depositing a sacrificial layer surrounding the fin-shaped structure;
performing a second etch into the sacrificial layer to form an opening with a top layout corresponding to a top layout of the isolation wall;
filling the opening with dielectric material to form the isolation wall; and
removing the sacrificial layer.

3. The method according to claim 1, further comprising:
performing a lateral etch into sidewalls of the pair of source electrodes and a sidewall of the drain electrode to form a plurality of recesses; and
forming a plurality of source/drain liners respectively in the plurality of recesses before the depositing of the gate layer.

4. The method according to claim 1, further comprising:
forming an additional fin-shaped structure elongated in parallel with the fin-shaped structure, wherein the isolation wall extends laterally from the fin-shaped structure to the additional fin-shaped structure.

5. The method according to claim 4, further comprising:
performing a second etch into the gate layer and the isolation wall to cut the gate layer and the isolation wall at a boundary region laterally between the fin-shaped structure and the additional fin-shaped structure.

6. The method according to claim 1, wherein the forming of the fin-shaped structure comprises:
forming a pair of conductive lines laterally elongated in a first direction;
depositing an interlayer dielectric (ILD) layer over the pair of conductive lines;
depositing a conductive layer over the ILD layer; and
performing a second etch into the conductive layer, the ILD layer, and the pair conductive lines, wherein the pair of source electrodes are formed respectively from the pair of conductive lines and the drain electrode is formed from the conductive layer.

7. The method according to claim 1, further comprising:
forming a pair of storage structures over a substrate, wherein the source electrodes are formed respectively overlying and electrically coupled to the storage structures.

8. A method, comprising:
forming multiple conductive lines laterally elongated in a first direction;
depositing a conductive layer overlying and spaced from the multiple conductive lines;
performing a first etch into the conductive layer and the multiple conductive lines to form multiple fin-shaped structures laterally elongated in a second direction transverse to the first direction and in which multiple source electrodes are in multiple rows and multiple columns;
forming multiple isolation walls elongated in the first direction and respectively at boundary regions between the multiple rows;
depositing a multi-layer film overlying, and extending along individual sidewalls of, the multiple fin-shaped structures and the multiple isolation walls, wherein the multi-layer film comprises a gate layer and a semiconductor channel layer; and
segmenting the multi-layer film into multiple film stacks that are spaced from each other and individual to the multiple source electrodes.

9. The method according to claim 8, wherein the segmenting comprises:
performing a second etch to cut the multi-layer film at the boundary regions between the multiple rows and into multiple line-shaped segments; and
performing third etch to cut the multiple line-shaped segments at boundary regions between the multiple columns and into the multiple film stacks.

10. The method according to claim 8, wherein the method further comprises:
forming multiple word lines corresponding to the multiple rows and each overlying and electrically coupled to gate electrodes of film stacks in a corresponding row.

11. The method according to claim 8, further comprising:
depositing a protection layer overlying the multiple film stacks and extending along sidewalls of the multiple film stacks, wherein the protection layer is configured to block diffusion of hydrogen to the multiple film stacks.

12. The method according to claim 8, further comprising:
depositing a sacrificial layer overlying and filling gaps between the multiple fin-shaped structures;
performing a planarization into the sacrificial layer to clear the sacrificial layer from atop the multiple fin-shaped structures, wherein the multiple isolation walls are formed inset into the sacrificial layer; and
removing the sacrificial layer.

13. A semiconductor structure, comprising:
a first source electrode and a second source electrode over a substrate;
a drain electrode overlying and spaced from the first and second source electrodes;
a first gate electrode overlying the drain electrode and extending along a sidewall of the drain electrode and a sidewall of the first source electrode that face a first direction; and
a second gate electrode overlying the drain electrode and extending along the sidewall of the drain electrode and a sidewall of the second source electrode that face the first direction,
wherein the first and second gate electrodes are spaced from each other along the sidewall of the drain electrode.

14. The semiconductor structure according to claim 13, wherein the first gate electrode has a dimension extending in the first direction, and wherein a value of the dimension at a top of the first source electrode is less than or equal to a value of the dimension at a bottom of the first source electrode.

15. The semiconductor structure according to claim 13, wherein the first gate electrode has a dimension less than a dimension of the first source electrode at an elevation closer to a top surface of the first source electrode than to a bottom surface of the first source electrode, and wherein the dimension of the first source electrode and the dimension of the first gate electrode extend laterally in a second direction transverse to the first direction.

16. The semiconductor structure according to claim 13, further comprising:
a first semiconductor channel within which the first gate electrode is laterally recessed, wherein the first semiconductor channel laterally separates the first gate electrode from the second gate electrode along the sidewall of the drain electrode.

17. The semiconductor structure according to claim 13, further comprising:
an interlayer dielectric (ILD) layer overlying the first source electrode and underlying the drain electrode, wherein the sidewall of the first source electrode, the sidewall of the drain electrode, and a sidewall of the ILD layer form a common sidewall facing the first direction.

18. The semiconductor structure according to claim 13, further comprising:
an interlayer dielectric (ILD) layer overlying the first source electrode and underlying the drain electrode; and
a pair of semiconductor liners respectively underlying and overlying the ILD layer and separating the drain electrode and the first source electrode from the first gate electrode.

19. The semiconductor structure according to claim 13, further comprising:
a protection layer overlying and spaced from the first gate electrode and extending along a sidewall of the first gate electrode, from a top of the first gate electrode to an elevation recessed below a bottom of the first gate electrode; and
a via extending through the protection layer to the gate electrode.

20. The semiconductor structure according to claim 13, further comprising:
a third source electrode over the substrate and bordering the first source electrode in a row that extends in the first direction;
an additional drain electrode overlying the third source electrode; and
a third gate electrode overlying the additional drain electrode and extending along a sidewall of the additional drain electrode and a sidewall of the third source electrode that face the first direction, wherein the third gate electrode is spaced from the first gate electrode.
